(19) United States
(12) Patent Application Publication
(10) Pub. No.: US 2026/0293463 A1
(43) Pub. Date: Sep. 24, 2026

(54) DISPLAY SUBSTRATE AND MANUFACTURING METHOD THEREFOR, AND DISPLAY APPARATUS

(71) Applicants: Chongqing BOE Display Technology Co.,Ltd., Chongqing (CN); BOE Technology Group Co., Ltd., Beijing (CN)

(72) Inventors: Rui WANG, Beijing (CN); Xiaoling HE, Beijing (CN); Runxin ZHANG, Beijing (CN); Ming HU, Beijing (CN); Chao ZENG, Beijing (CN); Haijun QIU, Beijing (CN); Xinyin WU, Beijing (CN); Xueguang HAO, Beijing (CN)

(21) Appl. No.: 19/482,209

(22) PCT Filed: Jan. 17, 2025
(86) PCT No.: PCT/CN2025/073055

§ 371 Date: Nov. 6, 2025

(30) Foreign Application Priority Data
Jan. 31, 2024 (CN) 202410139402.3

(51) Int. Cl. H10K 59/131; H10K 59/12

(52) U.S. Cl. CPC H10K 59/131; H10K 59/1201

(57) ABSTRACT

A display substrate and a manufacturing method therefor, and a display apparatus. The display substrate comprises multiple first regions and second regions alternately arranged; in the direction perpendicular to the display substrate, a display region comprises a driving structure layer and a light-emitting structure layer; a driving structure layer of each first region comprises multiple pixel driving circuits, a driving structure layer of each second region comprises at least one gate driving apparatus and/or at least one signal wire, a light-emitting structure layer of each first region comprises multiple first light-emitting devices, a light-emitting structure layer of each second region comprises multiple second light-emitting devices; at least one first light-emitting device in each first region is connected to at least one pixel driving circuit in first region, and at least one second light-emitting device in each second region is connected to at least one pixel driving circuit in first region.

### CROSS-REFERENCE TO RELATED APPLICATIONS

The present application is a U.S. National Phase Entry of International Application No. PCT/CN2025/073055 having an international filing date of Jan. 17, 2025, which claims priority to Chinese Patent Application No. 202410139402.3 filed to the CNIPA on Jan. 31, 2024, contents of which should be construed as being incorporated into the present application by reference in their entireties.

### TECHNICAL FIELD

The present disclosure relates to, but is not limited to, the field of display technologies, and particularly to a display substrate and a manufacturing method therefor, and a display apparatus.

### BACKGROUND

An organic light emitting diode (OLED) and a quantum dot light emitting diode (QLED) are active light emitting display devices and have advantages of self-illumination, a wide viewing angle, a high contrast ratio, low power consumption, an extremely high reaction speed, lightness and thinness, flexibility, and a low cost, etc. With constant development of display technologies, a flexible display device (Flexible Display) in which an OLED or a QLED is used as a light emitting device and signal control is performed through a thin film transistor (TFT) has become a mainstream product in the field of display at present.

### SUMMARY

The following is a summary of subject matters described herein in detail. This summary is not intended to limit the protection scope of claims.

In one aspect, the present disclosure provides a display substrate including a plurality of first regions and a plurality of second regions, wherein a first region of the plurality of first regions and a second region of the plurality of second regions are in a shape of a strip extending along a second direction, the plurality of first regions and the plurality of second regions are alternately disposed along a first direction, the first direction and the second direction intersects; in a direction perpendicular to the display substrate, a display region includes a drive structure layer disposed on a base substrate and a light emitting structure layer disposed on a side of the drive structure layer away from the base substrate; a drive structure layer of the first region includes a plurality of pixel drive circuits, a drive structure layer of the second region includes at least one gate drive apparatus and/or at least one signal trace, a light emitting structure layer of the first region includes a plurality of first light emitting devices, and a light emitting structure layer of the second region includes a plurality of second light emitting devices; at least one first light emitting device in the first region is connected to at least one pixel drive circuit in the first region, and at least one second light emitting device in the second region is connected to at least one pixel drive circuit in the first region.

In an exemplary embodiment, the drive structure layer of the first region includes a plurality of circuit repeating units, an orthographic projection of at least one circuit repeating unit on the base substrate has a first area, the light emitting structure layer of the first region includes a plurality of light emitting repeating units, an orthographic projection of at least one light emitting repeating unit on the base substrate has a second area, and a ratio of the first area to the second area is 0.95 to 1.05; the at least one circuit repeating unit includes M+m pixel drive circuits, and the at least one light emitting repeating unit includes M first light emitting devices; wherein M is an integer multiple of 2 or an integer multiple of 3, and m is a positive integer greater than or equal to 1.

In an exemplary embodiment, a pixel drive circuit in the at least one circuit repeating unit at least includes a first pixel drive circuit and a second pixel drive circuit, at least one first pixel drive circuit is connected to the at least one first light emitting device, and an orthographic projection of the at least one first pixel drive circuit on the base substrate is at least partially overlapped with an orthographic projection of the at least one first light emitting device on the base substrate; at least one second pixel drive circuit is connected to the at least one second light emitting device through an anode connection line, and an orthographic projection of the at least one second pixel drive circuit on the base substrate is not overlapped with an orthographic projection of the at least one second light emitting device on the base substrate.

In an exemplary embodiment, the second region has a first center line that is a straight line bisecting the second region in the first direction and extending along the second direction; the second region at least includes a first side repeating unit located at a side of the first center line in an opposite direction of the first direction and a second side repeating unit located at a side of the first center line in the first direction, and the first side repeating unit and the second side repeating unit each includes N second light emitting devices, and N is an integer multiple of 3 or an integer multiple of 4.

In an exemplary embodiment, the first region at least includes a first side region located at a side of the second region in an opposite direction of the first direction, and a second side region located at a side of the second region in the first direction; at least one second light emitting device in the first side repeating unit is connected to at least one second pixel drive circuit in the first side region through an anode connection line, and at least one second light emitting device in the second side repeating unit is connected to at least one second pixel drive circuit in the second side region through an anode connection line.

In an exemplary embodiment, the first side region at least includes a first circuit repeating unit and a second circuit repeating unit, the first circuit repeating unit is located at a side of the second region in an opposite direction of the first direction, the second circuit repeating unit is located at a side of the first circuit repeating unit away from the second region; the second side region at least includes an eleventh circuit repeating unit and a twelfth circuit repeating unit, the eleventh circuit repeating unit is located at a side of the second region in the first direction, and the twelfth circuit repeating unit is located at a side of the eleventh circuit repeating unit away from the second region; the first side repeating unit includes a first light emitting device group and a second light emitting device group sequentially disposed along the first direction, and the second side repeating unit includes a third light emitting device group and a fourth light emitting device group sequentially disposed along the first direction; at least one second light emitting device in the first light emitting device group is connected to at least one second pixel drive circuit in the first circuit repeating unit through a first anode connection line, at least one second light emitting device in the second light emitting device group is connected to at least one second pixel drive circuit in the second circuit repeating unit through a second anode connection line, at least one second light emitting device in the third light emitting device group is connected to at least one second pixel drive circuit in the eleventh circuit repeating unit through an eleventh anode connection line, and at least one second light emitting device in the fourth light emitting device group is connected to at least one second pixel drive circuit in the twelfth circuit repeating unit through a twelfth anode connection line.

In an exemplary embodiment, a second length of at least one second anode connection line is greater than a first length of at least one first anode connection line, a fourth length of at least one twelfth anode connection line is greater than a third length of at least one eleventh anode connection line, and the first length, the second length, the third length, and the fourth length are dimensions in the first direction.

In an exemplary embodiment, the third length of the at least one eleventh anode connection line is greater than the first length of the at least one first anode connection line, and the fourth length of the at least one twelfth anode connection line is greater than the second length of the at least one second anode connection line.

In an exemplary embodiment, a material of the anode connection line is a metal material, or the material of the anode connection line is a transparent conductive material.

In an exemplary embodiment, a first light emitting device of the plurality of first light emitting devices and a second light emitting device of the plurality of second light emitting devices each include an anode, an anode of at least one second light emitting device is connected to at least one second pixel drive circuit through the anode connection line, at least one anode connection line is in a shape of a straight line or bend line extending along the first direction, and an orthographic projection of the at least one anode connection line on the base substrate is at least partially overlapped with an orthographic projection of the anode of at least one first light emitting device on the base substrate.

In an exemplary embodiment, the first region further includes at least one dummy connection line, the at least one dummy connection line is in a shape of a straight line or a bend line extending along the first direction, and an orthographic projection of the at least one dummy connection line on the base substrate is at least partially overlapped with an orthographic projection of an anode of at least one first light emitting device on the base substrate.

In an exemplary embodiment, the first region at least includes a normal region and a connection line region, the normal region is a region where the anode connection line is not provided, and the connection line region is a region where the anode connection line is provided; an orthographic projection of at least one anode in the normal region on the base substrate is at least partially overlapped with orthographic projections of K1 dummy connection lines on the base substrate, an orthographic projection of at least one anode in the connection line region on the base substrate is at least partially overlapped with orthographic projections of K2 dummy connection lines and K3 anode connection lines on the base substrate, wherein K1-K2+K3, K1, K2, and K3 are all positive integers greater than or equal to 1.

In an exemplary embodiment, an arrangement of dummy connection lines in the normal region is the same as an arrangement of dummy connection lines and anode connection lines in the connection line region, and the arrangement is any one or more of: a position of a connection line in the second direction, a width of a connection line, and a spacing between adjacent connection lines, wherein the width and the spacing are dimensions in the second direction.

In an exemplary embodiment, a trace density of dummy connections line in the normal region is the same as a trace density of dummy connection lines and anode connection lines in the connection line region, and the trace density is an area of connection lines per unit area.

In an exemplary embodiment, at least one dummy connection line is connected to at least one signal connection line through at least one trace connection line, the trace connection line is in a shape of a straight line or a bend line extending along the second direction, the trace connection line is disposed between two anodes adjacent in the first direction, and an orthographic projection of the trace connection line on the base substrate is not overlapped with orthographic projections of the anodes on the base substrate.

In an exemplary embodiment, the signal connection line is in a shape of a straight line or a bend line extending along the first direction; at least one signal connection line is connected to a first power supply line which serves as the signal trace and a main body portion of which extends along the second direction to form a mesh communication structure for transmitting a first power supply signal, and/or at least one signal connection line is connected to a second power supply line which serves as the signal trace and a main body portion of which extends along the second direction to form a mesh communication structure for transmitting a second power supply signal, and/or at least one signal connection line is connected to an initial signal line which serves as the signal trace and a main body portion of which extends along the second direction to form a mesh communication structure for transmitting an initial signal.

In an exemplary embodiment, the at least one gate drive apparatus includes a plurality of gate drive circuits sequentially disposed and cascaded along the second direction, at least one gate drive circuit is connected to a first clock signal line and a second clock signal line, the first clock signal line and the second clock signal line are in a shape of a straight line or a bend line extending along the second direction; in at least one second region, an orthographic projection of the first power supply line on the base substrate is at least partially overlapped with orthographic projections of the first clock signal line and the second clock signal line on the base substrate, and/or an orthographic projection of the second power supply line on the base substrate is at least partially overlapped with orthographic projections of the first clock signal line and the second clock signal line on the base substrate, and/or an orthographic projection of the initial signal line on the base substrate is at least partially overlapped with orthographic projections of the first clock signal line and the second clock signal line on the base substrate.

In an exemplary embodiment, at least one signal connection line is disposed between two cascaded gate drive circuits in the second direction.

In another aspect, a display apparatus is further provided in the present disclosure, and the display apparatus includes the display substrate described above.

In yet another aspect, the present disclosure also provides a manufacturing method for a display substrate, the display substrate includes a plurality of first regions and a plurality of second regions, a first region of the plurality of first regions and a second region of the plurality of second regions are in a shape of a strip extending along a second direction, the plurality of first regions and the plurality of second regions are alternately disposed along a first direction, the first direction and the second direction intersect; and the manufacturing method includes: forming a drive structure layer on a base substrate; wherein the drive structure layer of the first region includes a plurality of pixel drive circuits, and the drive structure layer of the second region includes at least one gate drive apparatus and/or at least one signal trace; and forming a light emitting structure layer on a side of the drive structure layer away from the base substrate; wherein the light emitting structure layer of the first region includes a plurality of first light emitting devices, the light emitting structure layer of the second region includes a plurality of second light emitting devices, at least one first light emitting device in the first region is connected to at least one pixel drive circuit in the first region, and at least one second light emitting device in the second region is connected to at least one pixel drive circuit in the first region.

Other aspects of the present disclosure may be comprehended after the drawings and the detailed descriptions are read and understood.

### BRIEF DESCRIPTION OF DRAWINGS

Accompanying drawings are used to provide an understanding of technical solutions of the present disclosure, and form a part of the specification. The accompanying drawings and embodiments of the present disclosure are adopted to explain the technical solutions of the present disclosure, and do not form limitations on the technical solutions of the present disclosure.

FIG. 1 is a schematic diagram of a structure of a display apparatus.

FIG. 2 is a schematic diagram of a structure of a display substrate.

FIG. 3A is a schematic diagram of a planar structure of a display region in a display substrate.

FIG. 3B is a schematic diagram of a planar structure of a display region in another display substrate.

FIG. 4 is a schematic diagram of a sectional structure of a display region in a display substrate.

FIG. 5 is an equivalent circuit diagram of a pixel drive circuit.

FIG. 6 is a schematic diagram of a structure of a scan drive apparatus.

FIG. 7 is a schematic diagram of a structure of a display substrate according to an exemplary embodiment of the present disclosure.

FIG. 8 and FIG. 9 are enlarged views of region A in FIG. 7.

FIG. 10 is a schematic diagram of a connection between a pixel drive circuit and a light emitting device according to an embodiment of the present disclosure.

FIG. 11 is a schematic diagram of another connection between a pixel drive circuit and a light emitting device according to an embodiment of the present disclosure.

FIG. 12 is a schematic diagram of a dummy drive circuit according to an exemplary embodiment of the present disclosure.

FIG. 13 is a schematic diagram of an anode connection line according to an exemplary embodiment of the present disclosure.

FIG. 14 is a schematic diagram of an arrangement of second regions according to an exemplary embodiment of the present disclosure.

FIG. 15 is an enlarged view of region D in FIG. 14.

FIG. 16 is an enlarged view of region E in FIG. 14.

FIGS. 17 and 18 are schematic diagrams of gate lead-out lines according to an exemplary embodiment of the present disclosure.

Reference signs are described as follows.

| | | |
|---|---|---|
| 10-First region; | 10A-First side region | 10B-Second side region |
| 10-1-Normal region; | 10-2-Connection line region | 20-Second region; |
| 20A-First side repeating unit; | 20B-Second side repeating unit; | 30-Anode connection line; |
| 31-First anode connection line; | 32-Second anode connection line; | 33-Third anode connection line; |
| 34-Fourth anode connection line; | 40-Anode; | 41-Dummy connection line; |
| 42-Trace connection line; | 50-Signal connection line; | 60-Signal trace |
| 61-First power supply line; | 62-Second power supply line; | 63-Initial signal line; |
| 64-Data signal line; | 80-Integrated circuit; | 81-Gate lead-out line |
| 100-Display region; | 101-Base substrate; | 102-Drive structure layer; |
| 103-Light emitting structure layer; | 104-Encapsulation structure layer; | 200-Bonding region; |
| 300-Bezel region. | | |

### DETAILED DESCRIPTION

To make objectives, technical solutions, and advantages of the present disclosure clearer, the embodiments of the present disclosure will be described in detail below with reference to the accompanying drawings. It is to be noted that implementations may be implemented in multiple different forms. Those of ordinary skills in the art may easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementation of the present disclosure is not limited to shapes, numerical values, or the like shown in the drawings.

Ordinal numerals “first”, “second”, “third” and the like in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element with a certain electrical action. The “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, other elements with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulating layer” sometimes.

A triangle, rectangle, trapezoid, pentagon, or hexagon, or the like in the specification is not strictly defined, and it may be an approximate triangle, rectangle, trapezoid, pentagon, or hexagon, or the like. There may be some small deformations caused by tolerance, and there may be a chamfer, an arc edge, deformation, etc. In the present disclosure, “about” means that a boundary is not defined so strictly and numerical values within process and measurement error ranges are allowed.

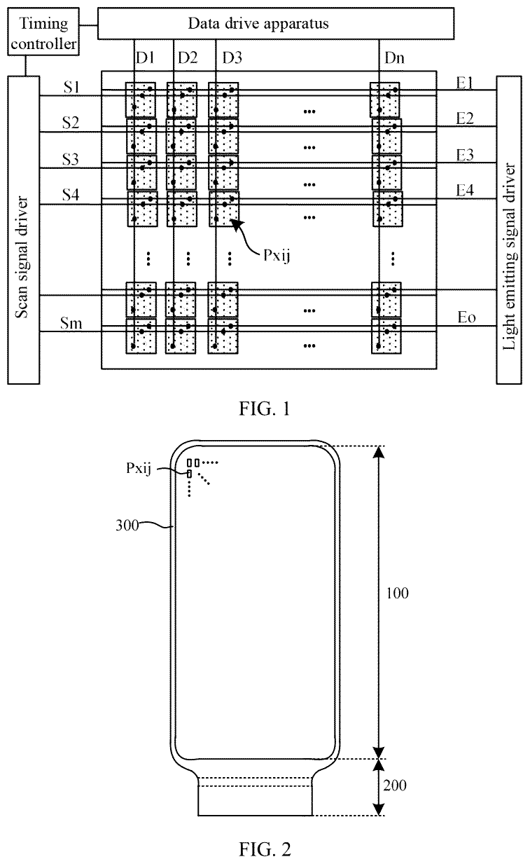

FIG. 1 is a schematic diagram of a structure of a display apparatus. As shown in FIG. 1, the display apparatus may include a timing controller, a data drive apparatus, a scan drive apparatus, and a pixel array, wherein, the timing controller is connected to the data drive apparatus and the scan drive apparatus, respectively, the data drive apparatus is connected to a plurality of data signal lines (D1 to Dn), respectively, and the scan drive apparatus respectively is connected to a plurality of scan signal lines (S1 to Sm) and a plurality of light emitting signal lines (E1 to Eo) respectively. The pixel array may include a plurality of sub-pixels Pxij, i and j may be natural numbers, at least one sub-pixel Pxij may include a circuit unit and a light emitting unit, the circuit unit may include, at least, a pixel drive circuit connected to a scan signal line, a light emitting signal line and a data signal line, respectively. The light emitting unit may include a light emitting device connected to a pixel drive circuit of a circuit unit. In an exemplary embodiment, the timing controller may provide the data drive apparatus with a grayscale value and a control signal which are suitable for a specification of the data drive apparatus, and may provide the scan drive apparatus with a clock signal, a scan start signal, an emission stop signal, and the like which are suitable for a specification of the scan drive apparatus. The data drive apparatus may generate data voltages to be provided to the data signal lines D1, D2, D3, . . . , and Dn using the grayscale value and the control signal that are received from the timing controller. For example, the data drive apparatus may sample the grayscale value using the clock signal and apply a data voltage corresponding to the grayscale value to the data signal lines D1 to Dn by taking a pixel row as a unit, wherein n may be a natural number. The scan drive apparatus may include at least one scan signal driver and at least one light emitting signal driver. The scan signal driver may generate scan signals to be provided to scan signal lines S1, S2, S3, . . . , and Sm by receiving a clock signal, a scan start signal, and the like from the timing controller. For example, the scan signal driver may sequentially provide scan signals with turning-on-level pulses to the scan signal lines S1 to Sm. For example, the scan signal driver may be constructed in a form of a shift register and may generate a scan signal in a manner in which the scan start signal provided in a form of an on-level pulse is transmitted to a next-stage circuit sequentially under control of the clock signal, wherein m may be a natural number. The light emitting signal driver may generate emission signals to be provided to emitting signal lines E1, E2, E3, . . . , and Eo by receiving the clock signal, the transmission stop signal, and the like from the timing controller. For example, the light emitting signal driver may sequentially provide emission signals with off-level pulses to the light emitting signal lines E1 to Eo. For example, the light emitting signal driver may be constructed in a form of a shift register and may generate an emission signal in a manner of transmitting sequentially the emission stop signal provided in a form of an off-level pulse to a next-stage circuit under control of the clock signal, wherein o may be a natural number. In an exemplary implementation, the pixel array may be arranged on a display substrate.

FIG. 2 is a schematic diagram of a structure of a display substrate. As shown in FIG. 2, the display substrate may include a display region 100, a bonding region 200 located on a side of the display region 100, and a bezel region 300 located on other sides of the display region 100. In an exemplary implementation, the display region 100 may be a flat region, including multiple sub-pixels Pxij that constitute a pixel array, wherein the multiple sub-pixels Pxij are configured to display a dynamic picture or a static image, and the display region 100 may be referred to as an Active Area (AA). In an exemplary embodiment, the display substrate may be a flexible substrate, so that the display substrate may be deformable, for example, be curled, bent, folded, or rolled.

In an exemplary implementation, the bonding region 200 may include a lead-out line region, a bending region, a drive chip region, and a bonding pin region, which are sequentially disposed along a direction away from the display region, and the lead-out line region is connected to the display region 100, and at least includes a data lead-out line. The bending region is connected to the lead-out line region and may at least include a composite insulation layer provided with a groove, the groove is configured to enable the bonding region to be bent to a back of the display region. The drive chip region may include an Integrated Circuit (IC for short), and the Integrated Circuit is configured to be connected with the plurality of data lead-out lines. The bonding pin region may include a Bonding Pad, and the Bonding Pad is configured to be bonded and connected with an external Flexible Printed Circuit (FPC for short).

In an exemplary embodiment, the bezel region 300 may include a circuit region, a power supply line region, a crack dam region, and a cutting region which are sequentially disposed in the direction away from the display region 100. The circuit region is connected to the display region 100 and may at least include a gate drive apparatus connected with a scan signal line and a light emitting signal line in the display region 100. The power supply line region is connected to the region and may at least include a bezel power supply lead that extends along a direction parallel to an edge of the display region and is connected with a cathode in the display region 100. The crack dam region is connected to the power supply line region and may at least include a plurality of cracks provided on the composite insulation layer. The cutting region is connected to the crack dam region and may at least include a cutting groove disposed on the composite insulation layer, wherein the cutting groove is configured, so that a cutting device respectively cuts along the cutting grooves after all films of the display substrate are manufactured.

In an exemplary implementation, the lead-out line region in the bonding region 200 and the power supply line region in the bezel region 300 may be provided with a dam spacer, the dam spacer may extend along a direction parallel to an edge of the display region to form an annular structure surrounding the display region 100, wherein the edge of the display region is an edge of a side of the display region close to the bonding region, or the bezel region.

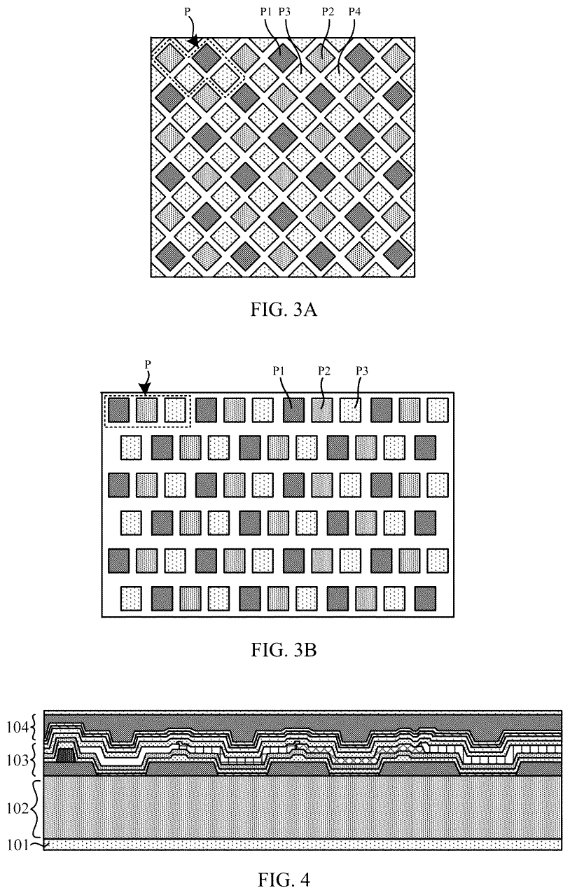

FIG. 3A is a schematic diagram of a planar structure of a display region in a display substrate. As shown in FIG. 3A, the display region may include a plurality of pixel units F arranged in a matrix, and at least one of the pixel units F may include a first sub-pixel P1, a second sub-pixel P2, a third sub-pixel P3, and a fourth sub-pixel P4. Each sub-pixel may include a circuit unit and a light emitting unit. The circuit unit may at least include a pixel drive circuit, the pixel drive circuit is connected with a scan signal line, a light emitting signal line, and a data signal line respectively, and the pixel drive circuit is configured to receive a data voltage transmitted by the data signal line and output a corresponding current to the light emitting unit under control of the scan signal line and the light emitting signal line. The light emitting unit may include a light emitting device connected with a pixel drive circuit of a sub-pixel where the light emitting device is located, and the light emitting device is configured to emit light with corresponding brightness in response to a current output by the pixel drive circuit of the sub-pixel where the light emitting device is located.

In an exemplary implementation, the first sub-pixels P1 may be red sub-pixels (R) emitting red light, the second sub-pixels P2 and the fourth sub-pixels P4 may be green sub-pixels (G) emitting green light, and the third sub-pixels P3 may be blue sub-pixels (B) emitting blue light. In an exemplary embodiment, a sub-pixel may be in a shape of a rectangle, a diamond, a pentagon, or a hexagon. The four sub-pixels may be arranged in an RGBG manner.

FIG. 3B is a schematic diagram of a planar structure of a display region in another display substrate. As shown in FIG. 3B, the pixel unit F may include three sub-pixels, the first sub-pixel P1 may be a red sub-pixel emitting red light, the second sub-pixel P2 may be a green sub-pixel emitting green light, and the third sub-pixel P3 may be a blue sub-pixel emitting blue light, and the three sub-pixels may be arranged in a Real RGB manner.

In another exemplary embodiment, wherein the three sub-pixels or four sub-pixels may be arranged side by side horizontally or side by side vertically, etc., which is not limited in the present disclosure.

FIG. 4 is a schematic diagram of a cross-sectional structure of a display region in a display substrate, illustrating a structure of four sub-pixels in the display region. As shown in FIG. 4, on a plane perpendicular to the display substrate, the display region may include a drive structure layer 102 disposed on a base substrate 101, a light emitting structure layer 103 disposed on one side of the drive structure layer 102 away from the base substrate 101, and an encapsulation structure layer 104 disposed on one side of the light emitting structure layer 103 away from the base substrate 101. In some possible implementations, the display region may include other film layers, such as a touch structure layer, which is not limited here in the present disclosure.

In an exemplary embodiment, the base substrate 101 may be a flexible base substrate, or may be a rigid base substrate. The drive structure layer 102 may include a plurality of circuit units each of which may at least include a pixel drive circuit. The light emitting structure layer 103 may include multiple light emitting units. Each light emitting unit may include a light emitting device, and the light emitting device may at least include an anode, an organic emitting layer, and a cathode. The anode is connected with a pixel drive circuit. The organic emitting layer is connected with the anode. The cathode is connected with the organic emitting layer. The organic emitting layer emits light of a corresponding color under driving of the anode and the cathode. The encapsulation structure layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a stacked structure of inorganic material/organic material/inorganic material and ensure that external moisture cannot enter the light emitting structure layer 103.

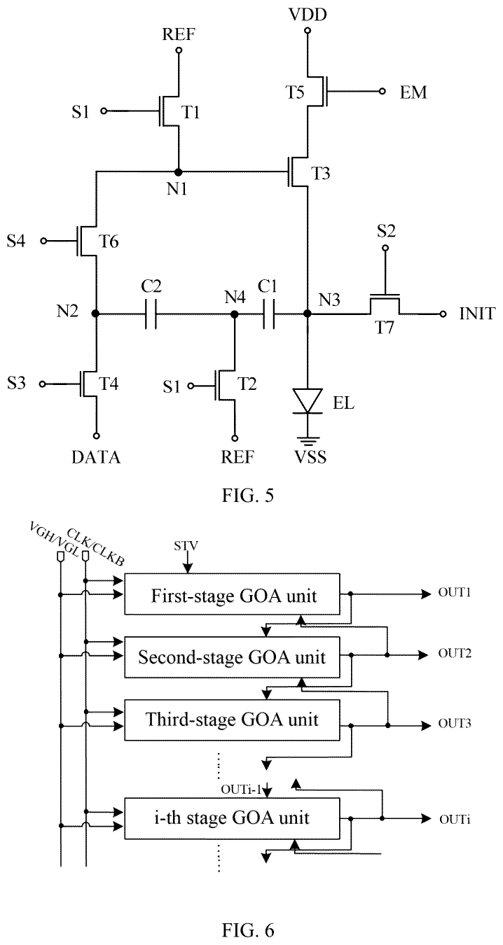

FIG. 5 is an equivalent circuit diagram of a pixel drive circuit. In an exemplary embodiment, the pixel drive circuit may have a structure of 3T1C, 4T1C, 5T1C, 5T2C, 6T1C, 7T1C, or 8T1C. As shown in FIG. 5, the pixel drive circuit may adopt a 7T2C structure including seven transistors (a first transistor T1 to a seventh transistor T7) and two capacitors (a first capacitor C1 and a second capacitor C2), and the pixel drive circuit is connected to nine signal lines (a first scan signal line S1, a second scan signal line S2, a third scan signal line S3, a fourth scan signal line S4, a light emitting signal line EM, a reference signal line REF, an initial signal line INIT, a data signal line DATA, and a first power supply line VDD), respectively.

In an exemplary embodiment, the pixel drive circuit may include a first node N1, a second node N2, a third node N3, and a fourth node N4. The first node N1 is respectively connected to a second electrode of the first transistor T1, a first electrode of the sixth transistor T6, and a gate electrode of the third transistor T3, the second node N2 is respectively connected to a second electrode of the fourth transistor T4, a second electrode of the sixth transistor T6, and a second terminal of the second capacitor C2, the third node N3 is respectively connected to a second electrode of the third transistor T3, a second electrode of the seventh transistor T7, and a second terminal of the first capacitor C1, and the fourth node N4 is connected to a second electrode of the second transistor T2, a first terminal of the first capacitor C1, and a first terminal of the second capacitor C2, respectively.

In an exemplary embodiment, the first transistor T1 may be referred to as a first reset transistor, a gate electrode of the first transistor T1 is connected to the first scan signal line S1, a first electrode of the first transistor T1 is connected to the reference signal line REF, and a second electrode of the first transistor T1 is connected to the first node N1.

In an exemplary embodiment, the second transistor T2 may be referred to as a second reset transistor, a gate electrode of the second transistor T2 is connected to the first scan signal line S1, a first electrode of the second transistor T2 is connected to the reference signal line REF, and the second electrode of the second transistor T2 is connected to the fourth node N4.

In an exemplary embodiment, the third transistor T3 may be referred to as a drive transistor. The gate electrode of the third transistor T3 is connected to the first node N1, the first electrode of the third transistor T3 is connected to the second electrode of the fifth transistor T5, and the second electrode of the third transistor T3 is connected to the third node N3.

In an exemplary implementation, the fourth transistor T4 may be referred to as a data writing transistor, a gate electrode of the fourth transistor T4 is connected to the third scan signal line S3, a first electrode of the fourth transistor T4 is connected to a data signal line DATA, and the second electrode of the fourth transistor T4 is connected to the second node N2.

In an exemplary embodiment, the fifth transistor T5 may be referred to as a light emitting control transistor, a gate electrode of the fifth transistor T5 is connected to the light emitting signal line EM, a first electrode of the fifth transistor T5 is connected to the first power supply line VDD, and the second electrode of the fifth transistor T5 is connected to the first electrode of the third transistor T3.

In an exemplary embodiment, the sixth transistor T6 may be referred to as a data control transistor, a gate electrode of the sixth transistor T6 is connected to the fourth scan signal line S4, a first electrode of the sixth transistor T6 is connected to the first node N1, and a second electrode of the sixth transistor T6 is connected to the second node N2.

In an exemplary embodiment, the seventh transistor T7 may be referred to as a third reset transistor, a gate electrode of the seventh transistor T7 is connected to the second scan signal line S2, a first electrode of the seventh transistor T7 is connected to the initial signal line INIT, and a second electrode of the seventh transistor T7 is connected to the third node N3.

In an exemplary implementation, the first electrode of the light emitting device EL is connected to the third node N3, and the second electrode of the light emitting device EL is connected to the second power supply line VSS. The light emitting device EL may be an OLED, including a first electrode (an anode), an organic light emitting layer, and a second electrode (a cathode) which are stacked, or may be a QLED including a first electrode (an anode), a quantum dot light emitting layer, and a second electrode (a cathode) which are stacked.

In an exemplary embodiment, the first power supply line VDD is configured to provide a constant first voltage signal to the pixel drive circuit, the second power supply line VSS is configured to provide a constant second voltage signal to the light emitting device, and the first voltage signal is a high-level signal and the second voltage signal is a low-level signal. The reference signal line and the initial voltage signal may be constant voltage signals, which is not limited here in the present disclosure.

In an exemplary implementation, the seven transistors of the pixel drive circuit may be P-type transistors, or may be N-type transistors. Use of a same type of transistors in a pixel drive circuit may simplify a process flow, reduce a process difficulty of a display panel, and improve a product yield. In some possible implementations, the seven transistors in the pixel drive circuit may include P-type transistor(s) and N-type transistor(s).

In an exemplary implementation, the seven transistors in the pixel drive circuit may be low temperature poly-silicon thin film transistors, or may be oxide thin film transistors, or may be low temperature poly-silicon thin film transistor(s) and oxide thin film transistor(s). An active layer of the low temperature poly-silicon thin film transistor is made of Low Temperature Poly-Silicon (LTPS), and an active layer of an oxide thin film transistor is made of an oxide semiconductor (Oxide). The low temperature poly-silicon thin film transistor has advantages such as high mobility and fast charging, and the oxide thin film transistor has advantages such as high electron mobility, low operating voltage, and low leakage current. The low temperature poly-silicon thin film transistor and the oxide thin film transistor are integrated on one display substrate to form an LTPO (Low Temperature Polycrystalline+Oxide) display substrate, so that advantages of both the low temperature poly-silicon thin film transistor and the oxide thin film transistor can be utilized, low-frequency drive can be achieved, power consumption can be decreased, and display quality can be improved.

FIG. 6 is a schematic diagram of a structure of a scan drive apparatus. In an exemplary embodiment, the scan drive apparatus may include a gate drive apparatus (a scan signal driver) that provides a scan signal and a gate drive apparatus (a light emitting signal driver) that provides a light emitting control signal. The gate drive apparatus may include a plurality of cascaded gate drive circuits (GOA circuits), the GOA circuit converts the clock signal into on/off voltages and output them to the display region, respectively, multi-stage GOA circuits are connected to scan signal lines or light emitting signal lines in a plurality of unit rows, and the on voltage is output by each GOA circuit in sequence and in turn to realize scanning of a plurality of unit rows in the display region row by row. As shown in FIG. 6, the gate drive apparatus may include a first-stage GOA circuit, a second-stage GOA circuit, a third-stage GOA circuit, . . . , and the first-stage GOA circuit may generate a scan signal OUT1 to provide to the pixel drive circuits in the first unit row in the display region, according to an initial signal provided by an initial signal line STV, a clock signal provided by a clock signal line CLK/CLKB, a signal provided by a high-level signal line VGH/low-level signal line VGL, and the like. The i-th stage GOA circuit may generate a scan signal OUTi to provide to the pixel drive circuits in the i-th unit row in the display region, according to a scan signal OUTi−1 generated by the (i−1)-th stage GOA circuit, a first clock signal provided by the first clock signal line CLK, a second clock signal provided by the second clock signal line CLKB, a high-level signal provided by the high-level signal line VGH, a low-level signal provided by the low-level signal line VGL, and the like, where i is a positive integer greater than 1.

Currently, as resolution of the display apparatus is gradually improved, and in order to ensure reliability and functionality of a bezel region, a bezel width of the existing display apparatus is about 1.5 mm or more. Resolution (Pixels Per Inch, PPI for short) refers to the number of pixel units per unit area, which may be called pixel density. The higher the PPI value, the higher the density of the display apparatus to display the picture, and the richer the details of the picture. Since improvement of resolution not only needs increasing the number of gate drive circuits in the bezel region, thereby increasing an area occupied by the gate drive circuit, but also needs increasing a width of a power supply lead in the bezel region to reduce impedance and voltage drop of the power supply lead and ensure the uniformity of the display brightness. Therefore, it is a challenge to reduce the width of the bezel for the structure in which the gate drive circuits are provided in the bezel region.

In order to effectively reduce the bezel width of the display apparatus and realize a narrow bezel of the display apparatus, an exemplary embodiment of the present disclosure provides a display substrate in which a gate drive apparatus is disposed in a display region (Gate Driver In AA, GIA for short). In an exemplary embodiment, the display substrate may at least include a display region and a bezel region located on at least one side of the display region. The display region may include a plurality of first regions and a plurality of second regions, a first region of the plurality of first regions and a second region of the plurality of second regions may be in a shape of a strip extending along a second direction, the plurality of first regions and the plurality of second regions may be alternately disposed in the first direction, and the first direction and the second direction intersect. On a direction perpendicular to the display substrate, the display region may include a drive structure layer disposed on a base substrate, and a light emitting structure layer disposed on a side of the drive structure layer away from the base substrate. The drive structure layer of the first region may include a plurality of pixel drive circuits, the drive structure layer of the second region may include at least one gate drive apparatus and/or at least one signal trace, and the light emitting structure layers of the first region and the second region may include a plurality of light emitting devices; at least one light emitting device in the first region is connected to at least one pixel drive circuit in the first region, and at least one light emitting device in the second region is connected to at least one pixel drive circuit in the first region.

In an exemplary embodiment, the drive structure layer of the first region may include a plurality of circuit repeating units, an orthographic projection of the circuit repeating unit on the base substrate has a first area, the light emitting structure layer of the first region may include a plurality of light emitting repeating units, an orthographic projection of the light emitting repeating unit on the base substrate has a second area, and a ratio of the first area to the second area is 0.95 to 1.05; at least one circuit repeating unit may include M+m pixel drive circuits, and at least one light emitting repeating unit may include M first light emitting devices; M is an integer multiple of 2 or an integer multiple of 3, and m is a positive integer greater than or equal to 1.

In an exemplary embodiment, the light emitting structure layer of the second region may include a first side repeating unit and a second side repeating unit, the first side repeating unit and the second side repeating unit each include N light emitting devices, and N is an integer multiple of 3 or an integer multiple of 4.

In an exemplary embodiment, the pixel drive circuit in at least one circuit repeating unit may at least include a first pixel drive circuit and a second pixel drive circuit, the light emitting device in at least one light emitting repeating unit may include a first light emitting device, and the light emitting device in at least one second repeating unit may include a second light emitting device; at least one first pixel drive circuit is connected to at least one first light emitting unit, an orthographic projection of the at least one first pixel drive circuit on the base substrate is at least partially overlapped with an orthographic projection of the at least one first light emitting device on the base substrate; at least one second pixel drive circuit is connected to at least one second light emitting device through an anode connection line, and an orthographic projection of the at least one second pixel drive circuit on the base substrate is not overlapped with an orthographic projection of the at least one second light emitting device on the base substrate.

In an exemplary embodiment, the first light emitting device and the second light emitting device each include an anode, the anode of the at least one second light emitting device is connected to the at least one second pixel drive circuit through the anode connection line, at least one anode connection line is in a shape of a straight line or bend line extending along the first direction, and an orthographic projection of the at least one anode connection line on the base substrate is at least partially overlapped with an orthographic projection of the anode of the at least one first light emitting device on the base substrate.

In an exemplary embodiment, the drive structure layer of the first region further includes at least one dummy connection line, the at least one dummy connection line is in a shape of a straight line or a bend line extending along the first direction, and an orthographic projection of the at least one dummy connection line on the base substrate is at least partially overlapped with an orthographic projection of the anode of at least one first light emitting device on the base substrate.

In an exemplary embodiment, the first region at least includes a normal region and a connection line region, the normal region is a region where the anode connection line is not provided, and the connection line region is a region where the anode connection line is provided; an orthographic projection of at least one anode in the normal region on the base substrate is at least partially overlapped with orthographic projections of K1 dummy connection lines on the base substrate, an orthographic projection of at least one anode in the connection line region on the base substrate is at least partially overlapped with orthographic projections of K2 dummy connection lines and K3 anode connection lines on the base substrate, wherein K1=K2+K3, K1, K2, and K3 are all positive integers greater than or equal to 1.

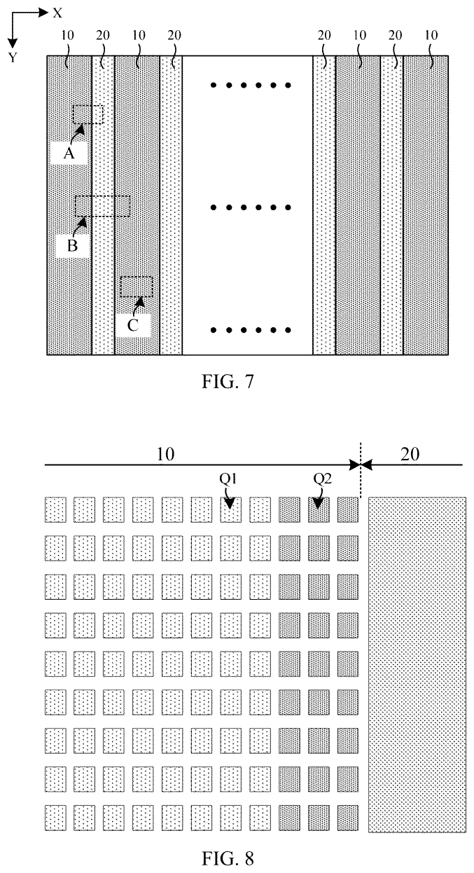

FIG. 7 is a schematic diagram of a structure of a display substrate according to an exemplary embodiment of the present disclosure. As shown in FIG. 7, on a plane parallel to the display substrate, the display substrate may at least include a display region and a bezel region located on at least one side of the display region. The display region may include a plurality of first regions 10 and a plurality of second regions 20, and the first region 10 and the second region 20 may both be in a shape of a strip extending along the second direction Y, and the plurality of first regions 10 and the plurality of second regions 20 may be alternately arranged along the first direction X to form a GIA structure, and the first direction X and the second direction Y intersect.

In an exemplary embodiment, widths of the plurality of first regions 10 may be substantially the same, widths of the plurality of second regions 20 may be substantially the same, the widths of the first regions 10 may be different from the widths of the second regions 20, and the widths may be dimensions in the first direction X. For example, the width of at least one first region 10 may be greater than the width of at least one second region 20.

In an exemplary embodiment, in a direction perpendicular to the display substrate, the display region may include a drive structure layer disposed on the base substrate, and a light emitting structure layer disposed on a side of the drive structure layer away from the base substrate. The drive structure layer of the first region 10 may include a plurality of circuit units, the circuit unit may at least include a pixel drive circuit, and the drive structure layer of the second region 20 may include a gate drive apparatus and/or a signal trace. The light emitting structure layer of the first region 10 may include a plurality of first light emitting units, the first light emitting unit may at least include a first light emitting device, the light emitting structure layer of the second region 20 may include a plurality of second light emitting units, and the second light emitting unit may at least include a second light emitting device, and the pixel drive circuit of the first region 10 is configured to provide a driving signal to the first light emitting device in the first region 10 and the second light emitting device in the second region 20 to drive the corresponding first light emitting device and second light emitting device to emit light.

In an exemplary embodiment, circuit units mentioned in the present disclosure refer to regions divided according to pixel drive circuits, and light emitting units mentioned in the present disclosure refer to regions divided according to light emitting devices. In an exemplary implementation, positions of the light emitting units may correspond to positions of the circuit units, or positions of the light emitting units may not correspond to positions of the circuit units, which is not limited here in the present disclosure. In the following description, the position, shape, dimension, and the like of the pixel drive circuit are equivalent to the position, shape, dimension, and the like of the circuit unit, and the position, shape, dimension, and the like of the light emitting device are equivalent to the position, shape, dimension, and the like of the light emitting unit.

In an exemplary embodiment, the drive structure layer of at least one first region 10 may include a plurality of circuit repeating units. The circuit repeating unit is a basic unit constituting the drive structure layer of the first region 10, and the drive structure layer of the first region 10 can be formed by repeatedly and continuously disposing the circuit repeating units along the first direction X and the second direction Y.

In an exemplary embodiment, the light emitting structure layer of at least one first region 10 may include a plurality of light emitting repeating units. The light emitting repeating unit is a basic unit constituting the light emitting structure layer of the first region 10, and the light emitting structure layer of the first region 10 can be formed by repeatedly and continuously providing the light emitting repeating units along the first direction X and the second direction Y.

In an exemplary embodiment, in at least one first region 10, the positions of the plurality of circuit repeating units and the positions of the plurality of light emitting repeating units may correspond one-to-one, an orthographic projection of at least one circuit repeating unit on the base substrate has a first area, an orthographic projection of at least one light emitting repeating unit on the base substrate has a second area, and a ratio of the first area to the second area may be about 0.95 to 1.05, that is, the area of the orthographic projection of the circuit repeating unit on the base substrate and the area of the orthographic projection of the light emitting repeating unit on the base substrate may be substantially the same.

In an exemplary embodiment, the dimension of at least one circuit repeating unit in the first direction X and the dimension of at least one light emitting repeating unit in the first direction X may be substantially the same, and the dimension of the at least one circuit repeating unit in the second direction Y and the dimension of the at least one light emitting repeating unit in the second direction Y may be substantially the same.

In an exemplary embodiment, at least one circuit repeating unit may include M+m pixel drive circuits sequentially disposed along the first direction X, and at least one light emitting repeating unit may include M first light emitting devices sequentially disposed along the first direction X, that is, an area of orthographic projections of the M+m pixel drive circuits on the base substrate is substantially the same as an area of orthographic projections of the M first light emitting devices on the base substrate.

In an exemplary embodiment, in at least one circuit repeating unit, the dimensions of the plurality of pixel drive circuits may be substantially the same. In the present disclosure, the dimension of a pixel drive circuit refers to a dimension of an orthographic projection of the pixel drive circuit on the base substrate. When the orthographic projection of the pixel drive circuit on the base substrate is rectangular, the dimensions may include any one or more of the following: a length of the orthographic projection in the first direction X, a length of the orthographic projection in the second direction Y, and an area of the orthographic projection. When the orthographic projection of the pixel drive circuit on the base substrate is circular or elliptical, the dimensions may include any one or more of the following: a radius of the orthographic projection, major and minor axes of the orthographic projection, and an area of the orthographic projection.

In an exemplary embodiment, in at least one light emitting repeating unit, the dimension of the plurality of first light emitting devices may be substantially the same. In the present disclosure, the dimension of a light emitting device refers to a dimension of an orthographic projection of the light emitting device on the base substrate. When the orthographic projection of the light emitting device on the base substrate is rectangular, the dimensions may include any one or more of the following: a length of the orthographic projection in the first direction X, a length of the orthographic projection in the second direction Y, and an area of the orthographic projection. When the orthographic projection of the light emitting device on the base substrate is circular or elliptical, the dimensions may include any one or more of the following: a radius of the orthographic projection, major and minor axes of the orthographic projection, and an area of the orthographic projection.

In an exemplary embodiment, in at least one first region 10, pixel drive circuits may be provided in the drive structure layer in a compression mode, while first light emitting devices may be provided in the light emitting structure layer in a normal (uncompressed) mode. For example, in the normal mode, M pixel drive circuits may be provided in one circuit repeating unit, and M first light emitting devices may be provided in one light emitting repeating unit. In the compression mode, the number of pixel drive circuits provided in the circuit repeating unit may be increased by using lateral compression, and m pixel drive circuits are added on the basis of M pixel drive circuits provided previously, so that M+m pixel drive circuits may be provided in one circuit repeating unit. Since the light emitting structure layer adopts the normal mode, M first light emitting devices are still provided in the light emitting repeating unit, and the area occupied by M+m pixel drive circuits is substantially the same as that occupied by M first light emitting devices.

In an exemplary embodiment, for a pixel arrangement of Real RGB, M may be an integer multiple of 3, such as 3, 6, 9, 12, 15 or 18, and m may be a positive integer greater than or equal to 1, such as 1, 2 or 3.

In an exemplary embodiment, for a pixel arrangement of RGGB arrangement, M may be an integer multiple of 2, such as 2, 4, 6, 8, 10, or 12, and m may be a positive integer greater than or equal to 1, such as 1, 2, or 3.

In an exemplary embodiment, one light emitting repeating unit may include 18 first light emitting devices sequentially disposed along the first direction X, and one circuit repeating unit may include 21 pixel drive circuits sequentially disposed along the first direction X, that is, M=18, m=3.

In another exemplary embodiment, one light emitting repeating unit may include 6 first light emitting devices sequentially disposed along the first direction X, and one circuit repeating unit may include 7 pixel drive circuits sequentially disposed along the first direction X, that is, M=6, m=1.

In an exemplary embodiment, the light emitting structure layer of at least one second region 20 may include a first side repeating unit and a second side repeating unit, and the first side repeating unit and the second side repeating unit may each include N second light emitting devices sequentially disposed along the first direction X.

In an exemplary embodiment, for the pixel arrangement of Real RGB, N may be an integer multiple of 3, such as 3, 6, 9, or 12.

In an exemplary embodiment, for the pixel arrangement of RGGB arrangement, N may be an integer multiple of 4, such as 4, 8, 12, or 16.

In an exemplary embodiment, the dimension of the second light emitting device in the second region 20 may be substantially the same as the dimension of the first light emitting device in the first region 10, and the arrangement of the plurality of second light emitting devices in the second region 20 may be substantially the same as the arrangement of the plurality of first light emitting devices in the first region 10.

In an exemplary embodiment, in at least one second region 20, both the first side repeating unit and the second side repeating unit may include 6 second light emitting devices sequentially disposed along the first direction X, that is, the light emitting structure layer of the second region 20 includes 12 second light emitting devices sequentially disposed along the first direction X.

In an exemplary embodiment, the drive structure layer of the second region 20 is provided with a gate drive apparatus and/or a signal trace, but without a pixel driving circuit, and the second light emitting device of the second region 20 needs to be connected to the pixel drive circuit in the first region 10 through an anode connection line.

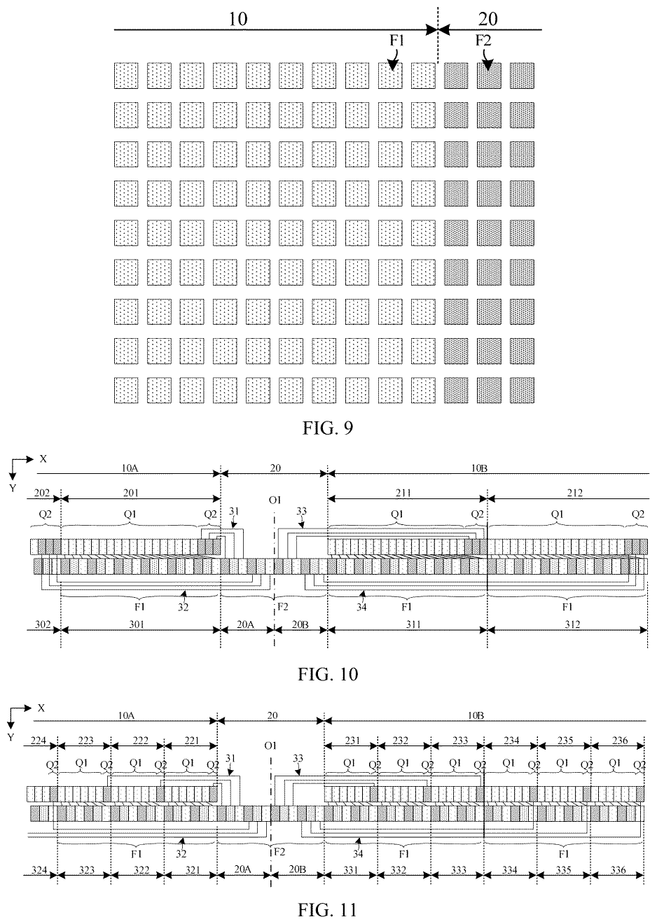

FIG. 8 and FIG. 9 are enlarged views of region A in FIG. 7, wherein FIG. 8 illustrates the structure of the drive structure layer in the region A, and FIG. 9 illustrates the structure of the light emitting structure layer in the region A. As shown in FIGS. 8 and 9, the plurality of pixel drive circuits in the first region 10 may include first pixel drive circuits Q1 and second pixel drive circuits Q2, the first region 10 includes a plurality of first light emitting devices F1, and the second region 20 includes a plurality of second light emitting devices F2.

In an exemplary embodiment, at least one first pixel drive circuit Q1 in the first region 10 is connected to at least one first light emitting unit F1 in the first region 10, an orthographic projection of the at least one first pixel drive circuit Q1 on the base substrate is at least partially overlapped with an orthographic projection of the at least one first light emitting device F1 on the base substrate, and the first pixel drive circuit Q1 is configured to provide a driving signal to the connected first light emitting device F1 to drive the corresponding first light emitting device F1 to emit light. In some examples, the plurality of first pixel drive circuits Q1 and the plurality of first light emitting devices F1 may be in a one-to-one relationship, that is, one first pixel drive circuit Q1 may be connected to one first light emitting device F1 and configured to drive the connected one first light emitting device F1 to emit light. Alternatively, the plurality of first pixel drive circuits Q1 and the plurality of first light emitting devices F1 may be in a one-to-multiple relationship, that is, one first pixel drive circuit Q1 may be connected to a plurality of first light emitting devices F1 and configured to drive the connected plurality of first light emitting devices F1 to emit light. Alternatively, the plurality of first pixel drive circuits Q1 and the plurality of first light emitting devices F1 may be in a multiple-to-one relationship, that is, a plurality of first pixel drive circuits Q1 may be connected to one first light emitting device F1 and configured to drive the first light emitting device F1 to emit light.

In an exemplary embodiment, at least one second pixel drive circuit Q2 in the first region 10 is connected to at least one second light emitting device F2 in the second region 20 through an anode connection line, an orthographic projection of the at least one second pixel drive circuit Q2 on the base substrate is not overlapped with an orthographic projection of the at least one second light emitting device F2 on the base substrate, and the second pixel drive circuit Q2 is configured to provide a driving signal to the connected second light emitting device F2 to drive the corresponding second light emitting device F2 to emit light. In some examples, the plurality of second pixel drive circuits Q2 and the plurality of second light emitting devices F2 may be in a one-to-one relationship, that is, one second pixel drive circuit Q2 may be connected to one second light emitting device F2 and configured to drive the connected one second light emitting device F2 to emit light. Alternatively, the plurality of second pixel drive circuits Q2 and the plurality of second light emitting devices F2 may be in a one-to-multiple relationship, that is, one second pixel drive circuit Q2 may be connected to a plurality of second light emitting devices F2 and configured to drive the connected plurality of second light emitting devices F2 to emit light. Alternatively, the plurality of second pixel drive circuits Q2 and the plurality of second light emitting devices F2 may be in a multiple-to-one relationship, that is, a plurality of second pixel drive circuits Q2 may be connected to one second light emitting device F2 and configured to drive the second light emitting device F2 to emit light.

In an exemplary embodiment, the dimensions of the first pixel drive circuit Q1 and the second pixel drive circuit Q2 may be substantially the same, and the dimensions of the first light emitting device F1 and the second light emitting device F2 may be substantially the same.

In an exemplary embodiment, the drive structure layer of the second region 20 may at least include one gate drive apparatus, or at least one signal trace, or may include at least one gate drive apparatus and at least one signal trace.

In an exemplary embodiment, the at least one gate drive apparatus may include any one or more of: a first gate drive apparatus that outputs a first scan signal line S1, a second gate drive apparatus that outputs a second scan signal line S2, a third gate drive apparatus that outputs a third scan signal line S3, a fourth gate drive apparatus that outputs a fourth scan signal line S4, and a fifth gate drive apparatus that outputs a light emitting signal line EM. The at least one signal trace may include any one or more of the following: a first power supply line, a second power supply line, and an initial signal line.

FIG. 10 is a schematic diagram of a connection between a pixel drive circuit and a light emitting device according to an exemplary embodiment of the present disclosure, and is an enlarged view of region B in FIG. 7. As shown in FIG. 10, the second region 20 may be located between two first regions 10, and the two first regions 10 may include a first side region 10A located on a side of the second region 20 in an opposite direction of the first direction X and a second side region 10B located on a side of the second region 20 in the first direction X. The second region 20 may have a first center line O1, which may be a straight line bisecting the second region 20 in the first direction X and extending along the second direction Y. The second region 20 at least includes a first side repeating unit 20A located at a side of the first center line O1 in an opposite direction of the first direction X and a second side repeating unit 20B located at a side of the first center line O1 in the first direction X. At least one second light emitting device F2 in the first side repeating unit 20A may be connected to at least one second pixel drive circuit Q2 in the first side region 10A through an anode connection line, and at least one second light emitting device F2 in the second side repeating unit 20B may be connected to at least one second pixel drive circuit Q2 in the second side region 10B through an anode connection line, that is, the second light emitting device F2 and the second pixel drive circuit Q2 located at a same side of the first center line O1 are connected correspondingly.

In an exemplary embodiment, the drive structure layer of the first region 10 is provided with a plurality of circuit repeating units, the light emitting structure layer of the first region 10 is provided with a plurality of light emitting repeating units, the drive structure layer of the second region 20 is provided with a gate drive apparatus and/or a signal trace (not shown), and the light emitting structure layer of the second region 20 is provided with a first side repeating unit 20A and a second side repeating unit 20B.

In an exemplary embodiment, the drive structure layer of the first side region 10A may at least include a first circuit repeating unit 201 and a second circuit repeating unit 202, the first circuit repeating unit 201 may be located on a side of the second region 20 in an opposite direction of the first direction X, and the second circuit repeating unit 202 may be located on a side of the first circuit repeating unit 201 away from the second region 20. The drive structure layer of the second side region 10B may at least include an eleventh circuit repeating unit 211 and a twelfth circuit repeating unit 212, the eleventh circuit repeating unit 211 is located on a side of the second region 20 in the first direction X, and the twelfth circuit repeating unit 212 is located on a side of the eleventh circuit repeating unit 211 away from the second region 20.

In an exemplary embodiment, the first circuit repeating unit 201, the second circuit repeating unit 202, the eleventh circuit repeating unit 211, and the twelfth circuit repeating unit 212 may each include 18 first pixel drive circuits Q1 and 3 second pixel drive circuits Q2, in at least one circuit repeating unit, the 18 first pixel drive circuits Q1 may be sequentially disposed along the first direction X, and the 3 second pixel drive circuits Q2 may be disposed on a side of the first pixel drive circuits Q1 in the first direction X.

In an exemplary embodiment, since the second pixel drive circuits Q2 in the circuit repeating unit are located at a side of the first pixel drive circuits Q1 in the first direction X, the positions of the second pixel drive circuits Q2 in the first circuit repeating unit 201 and the positions of the second pixel drive circuits Q2 in the eleventh circuit repeating unit 211 are not symmetrical with respect to the first center line O1, and the positions of the second pixel drive circuits Q2 in the second circuit repeating unit 202 and the positions of the second pixel drive circuits Q2 in the twelfth circuit repeating unit 212 are not symmetrical with respect to the first center line O1.

In an exemplary embodiment, the light emitting structure layer of the first side region 10A may at least include a first light emitting repeating unit 301 and a second light emitting repeating unit 302, the first light emitting repeating unit 301 may be located on a side of the second region 20 in an opposite direction of the first direction X, and the second light emitting repeating unit 302 may be located on a side of the first light emitting repeating unit 301 away from the second region 20. The light emitting structure layer of the second side region 10B may at least include an eleventh light emitting repeating unit 311 and a twelfth light emitting repeating unit 312, the eleventh light emitting repeating unit 311 is located on a side of the second region 20 in the first direction X, and the twelfth light emitting repeating unit 312 is located on a side of the eleventh light emitting repeating unit 311 away from the second region 20.

In an exemplary embodiment, the first light emitting repeating unit 301, the second light emitting repeating unit 302, the eleventh light emitting repeating unit 311, and the twelfth light emitting repeating unit 312 may each include 18 first light emitting devices F1. The first light emitting devices F1 may include a red light emitting device, a green light emitting device, and a blue light emitting device, and the red light emitting device, the green light emitting device, and the blue light emitting device may be periodically provided along the first direction X.

In an exemplary embodiment, the first side repeating unit 20A and the second side repeating unit 20B in the second region 20 may each include 6 second light emitting devices F2. The second light emitting devices F2 may include a red light emitting device, a green light emitting device, and a blue light emitting device, and the red light emitting device, the green light emitting device, and the blue light emitting device may be periodically provided along the first direction X.

In an exemplary embodiment, in at least one first region 10, the position of one circuit repeating unit corresponds one-to-one to the position of one light emitting repeating unit, and the dimension of the circuit repeating unit is substantially the same as the dimension of the light emitting repeating unit, which is equivalent to that the area occupied by 21 pixel drive circuits is substantially the same as that occupied by 18 light emitting devices.

In an exemplary embodiment, the position of the first circuit repeating unit 201 may correspond to the position of the first light emitting repeating unit 301, the position of the second circuit repeating unit 202 may correspond to the position of the second light emitting repeating unit 302, the position of the eleventh circuit repeating unit 211 may correspond to the position of the eleventh light emitting repeating unit 311, and the position of the twelfth circuit repeating unit 212 may correspond to the position of the twelfth light emitting repeating unit 312.

In an exemplary embodiment, in the corresponding circuit repeating unit and light emitting repeating unit, at least one first light emitting device F1 is directly connected to at least one first pixel drive circuit Q1, an orthographic projection of the at least one first light emitting device F1 on the base substrate is at least partially overlapped with an orthographic projection of the at least one first pixel drive circuit Q1 on the base substrate, and the first pixel drive circuit Q1 is configured to provide a driving signal to the connected first light emitting device F1 to drive the corresponding first light emitting device F1 to emit light.

In an exemplary embodiment, at least one second light emitting device F2 in the second region 20 is connected to at least one second pixel drive circuit Q2 in the first region 10 by an anode connection line, an orthographic projection of the at least one second light emitting device F2 on the base substrate is not overlapped with an orthographic projection of the at least one second pixel drive circuit Q2 on the base substrate, and the second pixel drive circuit Q2 is configured to provide a driving signal to the connected second light emitting device F2 to drive the corresponding second light emitting device F2 to emit light.

In an exemplary embodiment, the first side repeating unit 20A may at least include a first light emitting device group and a second light emitting device group sequentially disposed along the first direction X, the second side repeating unit 20B may at least include a third light emitting device group and a fourth light emitting device group sequentially disposed along the first direction X, and each light emitting device group may include 3 second light emitting devices F2. The 6 second light emitting devices F2 in the first and second light emitting device groups may be connected to the 6 second pixel drive circuits Q2 in the first side region 10A, and the 6 second light emitting devices F2 in the third and fourth light emitting device groups may be connected to the 6 second pixel drive circuits Q2 in the second side region 10B.

In an exemplary embodiment, the position of the first light emitting device group in the first side repeating unit 20A and the position of the fourth light emitting device group in the second side repeating unit 20B may be mirror-symmetric with respect to the first center line O1, and the position of the second light emitting device group in the first side repeating unit 20A and the position of the third light emitting device group in the second side repeating unit 20B may be mirror-symmetric with respect to the first center line O1.

In an exemplary embodiment, the 3 second light emitting devices F2 of the first light emitting device group in the first side repeating unit 20A may be connected to the 3 second pixel drive circuits Q2 in the first circuit repeating unit 201 through first anode connection lines 31, respectively, and the 3 second light emitting devices F2 of the second light emitting device group in the first side repeating unit 20A may be connected to the 3 second pixel drive circuits Q2 in the second circuit repeating unit 202 through second anode connection lines 32, respectively.

In an exemplary embodiment, the 3 second light emitting devices F2 of the third light emitting device group in the second side repeating unit 20B may be connected to the 3 second pixel drive circuits Q2 in the eleventh circuit repeating unit 211 through third anode connection lines 33, and the 3 second light emitting devices F2 of the fourth light emitting device group in the second side repeating unit 20B may be connected to the 3 second pixel drive circuits Q2 in the twelfth circuit repeating unit 212 through fourth anode connection lines 34.

In an exemplary embodiment, since the second circuit repeating unit 202 is located on a side of the first circuit repeating unit 201 away from the second region 20, a distance between the second pixel drive circuit Q2 in the second circuit repeating unit 202 and the first center line O1 is larger than a distance between the second pixel drive circuit Q2 in the first circuit repeating unit 201 and the first center line O1, so that a second length of at least one second anode connection line 32 is larger than a first length of at least one first anode connection line 31, and the first length and the second length may be dimensions in the first direction X.

In an exemplary embodiment, since the twelfth circuit repeating unit 212 is located on a side of the eleventh circuit repeating unit 211 away from the second region 20, a distance between the second pixel drive circuit Q2 in the twelfth circuit repeating unit 212 and the first center line O1 is larger than a distance between the second pixel drive circuit Q2 in the eleventh circuit repeating unit 211 and the first center line O1, so that a fourth length of at least one fourth anode connection line 34 is larger than a third length of at least one third anode connection line 33, and the third length and the fourth length may be dimensions in the first direction X.

In an exemplary embodiment, since a second pixel drive circuit Q2 is located at a side of a first pixel drive circuit Q1 in a circuit repeating unit in the first direction X, the distance between the second pixel drive circuit Q2 in the eleventh circuit repeating unit 211 and the first center line O1 is greater than a distance between the second pixel drive circuit Q2 in the first circuit repeating unit 201 and the first center line O1, and the distance between the second pixel drive circuit Q2 in the twelfth circuit repeating unit 212 and the first center line O1 is greater than a distance between the second pixel drive circuit Q2 in the second circuit repeating unit 202 and the first center line O1, so that lengths of the anode connection lines at two sides of the second region 20 are different, the third length of the at least one third anode connection line 33 is greater than first length of the at least one first anode connection line 31, and the fourth length of the at least one fourth anode connection line 34 is greater than second length of the at least one second anode connection line 32.

In an exemplary embodiment, the distance between the second pixel drive circuit Q2 in the second circuit repeating unit 202 and the first center line O1 may be greater than the distance between the second pixel drive circuit Q2 in the eleventh circuit repeating unit 211 and the first center line O1, and thus the second length of the at least one second anode connection line 32 may be greater than the third length of the at least one third anode connection line 33.

FIG. 11 is a schematic diagram of another connection between a pixel drive circuit and a light emitting device according to an exemplary embodiment of the present disclosure, and is an enlarged view of region B in FIG. 7. The connection structure between the pixel drive circuit and the light emitting device of the present embodiment is substantially the same as that described in FIG. 10, except that the circuit repeating unit of the present embodiment includes 6 first pixel drive circuits Q1 and 1 second pixel drive circuit Q2, and the light emitting repeating unit includes 6 first light emitting devices F1.

As shown in FIG. 11, the drive structure layer of the first side region 10A may at least include a twenty-first circuit repeating unit 221, a twenty-second circuit repeating unit 222, a twenty-third circuit repeating unit 223, and a twenty-fourth circuit repeating unit 224 disposed sequentially along a direction away from the second region 202. The drive structure layer of the second side region 10B may at least include a thirty-first circuit repeating unit 231, a thirty-second circuit repeating unit 232, a thirty-third circuit repeating unit 233, a thirty-fourth circuit repeating unit 234, a thirty-fifth circuit repeating unit 235, and a thirty-sixth circuit repeating unit 236, which are sequentially disposed in a direction away from the second region 202.

In an exemplary embodiment, the twenty-first circuit repeating unit 221 to the twenty-fourth circuit repeating unit 224 and the thirty-first circuit repeating unit 231 to the thirty-sixth circuit repeating unit 236 may each include 6 first pixel drive circuits Q1 and 1 second pixel drive circuit Q2, in at least one circuit repeating unit, the 6 first pixel drive circuits Q1 may be sequentially disposed along the first direction X, and the 1 second pixel drive circuit Q2 may be disposed on a side of the first pixel drive circuits Q1 in the first direction X.

In an exemplary embodiment, since the second pixel drive circuit Q2 in the circuit repeating unit is located on a side of the first pixel drive circuits Q1 in the first direction X, the positions of the second pixel drive circuits Q2 in the circuit repeating units at corresponding positions on two sides of the second region are not symmetrical with respect to the first center line O1. For example, the position of the second pixel drive circuit Q2 in the twenty-first circuit repeating unit 221 and the position of the second pixel drive circuit Q2 in the thirty-first circuit repeating unit 231 are not symmetrical with respect to the first center line O1.

In an exemplary embodiment, the light emitting structure layer of the first side region 10A may at least include a twenty-first light emitting repeating unit 321, a twenty-second light emitting repeating unit 322, a twenty-third light emitting repeating unit 323, and a twenty-fourth light emitting repeating unit 324 disposed sequentially along a direction away from the second region 202. The light emitting structure layer of the second side region 10B may at least include a thirty-first light emitting repeating unit 331, a thirty-second light emitting repeating unit 332, a thirty-third light emitting repeating unit 333, a thirty-fourth light emitting repeating unit 334, a thirty-fifth light emitting repeating unit 335, and a thirty-sixth light emitting repeating unit 336 disposed sequentially in a direction away from the second region 202.

In an exemplary embodiment, the twenty-first light emitting repeating unit 321 to the twenty-fourth light emitting repeating unit 324, the thirty-first light emitting repeating units 331 to the thirty-sixth light emitting repeating units 336 may each include 6 first light emitting devices F1, and the first side repeating unit 20A and the second side repeating unit 20B may each include 6 second light emitting devices F2.

In an exemplary embodiment, the 3 second light emitting devices F2 of the first light emitting device group in the first side repeating unit 20A may be connected to the second pixel drive circuits Q2 in the twenty-first circuit repeating unit 221 to the twenty-third circuit repeating unit 223 through first anode connection lines 31, respectively, and the 3 second light emitting devices F2 of the second light emitting device group in the first side repeating unit 20A may be connected to the second pixel drive circuits Q2 in the twenty-fourth circuit repeating unit 224 to the twenty-sixth circuit repeating unit through second anode connection lines 32, respectively.

In an exemplary embodiment, the 3 second light emitting devices F2 of the third light emitting device group in the second side repeating unit 20B may be connected to the second pixel drive circuits Q2 in the thirty-first circuit repeating unit 231 to the thirty-third circuit repeating unit 233 through third anode connection lines 33, respectively, and the 3 second light emitting devices F2 of the fourth light emitting device group in the second side repeating unit 20B may be connected to the second pixel drive circuits Q2 in the thirty-fourth circuit repeating unit 234 to the thirty-sixth circuit repeating unit 236 through fourth anode connection lines 34, respectively.

In an exemplary embodiment, a second length of at least one second anode connection line 32 is greater than a first length of at least one first anode connection line 31, and a fourth length of at least one fourth anode connection line 34 is greater than a third length of at least one third anode connection line 33.

In an exemplary embodiment, the third length of the at least one third anode connection line 33 is greater than the first length of the at least one first anode connection line 31, and the fourth length of the at least one fourth anode connection line 34 is greater than the second length of the at least one second anode connection line 32.

In an exemplary embodiment, the first anode connection line 31, the second anode connection line 32, the third anode connection line 33, and the fourth anode connection line 34 may be made of a metal material such as silver (Ag), copper (Cu), aluminum (Al), titanium (Ti), molybdenum (Mo), etc., or may be made of an alloy material composed of metals, such as an aluminum-neodymium alloy (AlNd) or a molybdenum-niobium alloy (MoNb), etc., and may be of a single-layer structure or a multi-layer composite structure, such as Ti/Al/Ti, or the like.

In another exemplary embodiment, the first anode connection line 31, the second anode connection line 32, the third anode connection line 33, and the fourth anode connection line 34 may be made of a transparent conductive material such as indium tin oxide (ITO) or indium zinc oxide (IZO). Since the film layer of indium tin oxide (ITO) or indium zinc oxide (IZO) is thin and transparent, the flatness of the anode can be improved and defects such as screen-off watermark (Mura) can be alleviated.

In yet another exemplary embodiment, a plurality of anode connection lines may be provided in one conductive layer, or may be provided in two or more conductive layers, which is not limited here in the present disclosure.

In an exemplary embodiment, that the light emitting device is connected to the pixel drive circuit through the anode connection line mentioned above means that the anode of the light emitting device is connected to the pixel drive circuit through the anode connection line.

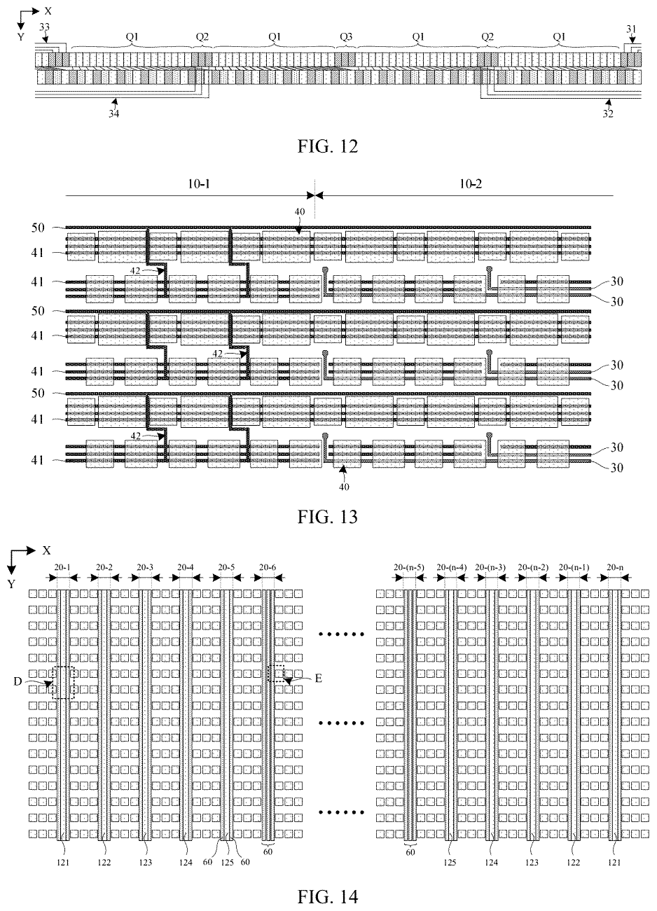

FIG. 12 is a schematic diagram of a dummy drive circuit according to an exemplary embodiment of the present disclosure, and is an enlarged view of region C in FIG. 7. As shown in FIG. 12, in at least one first region 10, the drive structure layer may include a plurality of first circuit units, a plurality of second circuit units, and at least one dummy circuit unit, the first circuit unit may at least include a first pixel drive circuit Q1, the second circuit unit may at least include a second pixel drive circuit Q2, and the dummy circuit unit may at least include a dummy drive circuit Q3.

In an exemplary embodiment, in at least one first region 10, the positions and structures of the first pixel drive circuits Q1 and the second pixel drive circuits Q2 are substantially the same as those of the foregoing embodiments, and the structure, arrangement, dimension, and the like of the dummy drive circuit Q3 may be substantially the same as those of the second pixel drive circuit Q2, except that the dummy drive circuit Q3 is not connected to any light emitting device.

In an exemplary embodiment, among a plurality of circuit repeating units in the first region, the second pixel drive circuits in a part of the circuit repeating units are connected to the second light emitting devices in the second region on a side of the first region in an opposite direction of the first direction X, the second pixel drive circuits in the another part of the circuit repeating units are connected to the second light emitting devices in the second region on a side of the first region in the first direction X. In the remaining circuit repeating units, M pixel drive circuits are connected to the first light emitting devices in the corresponding light emitting repeating units, and m pixel drive circuits serve as dummy drive circuits that are neither connected to the first light emitting devices nor to the second light emitting devices.

In an exemplary embodiment, in the first direction X, the dummy drive circuit Q3 may be provided at a middle position of the first region and at a side of the second pixel drive circuit Q2 away from the second region 20.

FIG. 13 is a schematic diagram of an anode connection line according to an exemplary embodiment of the present disclosure. As shown in FIG. 13, both the first light emitting device and the second light emitting device may include an anode, and that the first light emitting device is connected to the first pixel drive circuit mentioned above means that the anode of the first light emitting device is connected to the first pixel drive circuit, and that the second light emitting device is connected to the second pixel drive circuit through an anode connection line mentioned above means that the anode of the second light emitting device is connected to the second pixel drive circuit through the anode connection line.

In an exemplary embodiment, the anodes of the light emitting structure layers in the first region 10 and the second region 20 may be arranged in a real RGB mode or may be arranged in an RGBG mode, which is not limited here in the present disclosure.

In an exemplary embodiment, the anode connection line 30 may have a main body portion in a shape of a straight line or a bend line extending along the first direction X, an orthographic projection of the anode connection line 30 on the base substrate is at least partially overlapped with an orthographic projection of at least one anode 40 in the first region 10 on the base substrate, and the anode connection line 30 may serve as a lateral connection line.

In the present disclosure, “A extends in a B direction” refers to that A may include a main portion and a secondary portion connected to the main portion, wherein the main portion is a line, a line segment, or a strip-shaped body, the main portion extends in the B direction, and a length of the main portion extending in the B direction is greater than a length of the secondary portion extending in another direction. In following description, “A extends in a B direction” means “a main body portion of A extends in the B direction”.

In an exemplary embodiment, the anode connection lines 30 may be arranged to be as symmetrically distributed with respect to the anode 40 as much as possible to ensure the flatness of the anode.

In an exemplary embodiment, at least one first region 10 may be provided with at least one dummy connection line 41, the dummy connection line 41 may have a main body portion in a shape of a straight line or a bend line extending along the first direction X, an orthographic projection of the dummy connection line 41 on the base substrate is at least partially overlapped with an orthographic projection of at least one anode 40 on the base substrate, the dummy connection line 41 is configured to improve the flatness of the anode, and the dummy connection line 41 may serve as another lateral connection line.

In an exemplary embodiment, since the anode connection line 30 is provided at some of positions in the first region 10, the first region 10 may be divided into a normal region 10-1 and a connection line region 10-2 in the first direction X according to the presence or absence of the anode connection lines 30 as a division basis, the normal region 10-1 may be a region in which no anode connection line 30 is provided, and the connection line region 10-2 may be a region in which the anode connection lines 30 are provided.

In an exemplary embodiment, an orthographic projection of at least one anode 40 in the normal region 10-1 on the base substrate is at least partially overlapped with orthographic projections of K1 dummy connection lines 41 on the base substrate, i.e. the number of lateral connection lines, which overlap with one anode 40 in orthographic projections on the base substrate, in the normal region 10-1 is K1.

In an exemplary embodiment, an orthographic projection of at least one anode 40 in the connection line region 10-2 on the base substrate is at least partially overlapped with orthographic projections of the K2 dummy connection lines 41 on the base substrate, and the orthographic projection of the anode 40 on the base substrate is at least partially overlapped with orthographic projections of K3 anode connection lines 30 on the base substrate, i.e. the number of lateral connection lines which overlap with one anode 40, in orthographic projections on the base substrate, in the connection line region 10-2 is K2+K3.

In an exemplary embodiment, the number of lateral connection lines which overlap with at least one anode 40, in orthographic projections on the base substrate, in the normal region 10-1 may be substantially the same as that in the connection line region 10-2, that is, K1=K2+K3, and K1, K2, and K3 are all positive integers greater than or equal to 1.

In an exemplary embodiment, the arrangement of lateral connection lines (dummy connection lines) in the normal region 10-1 and the arrangement of lateral connection lines (dummy connection lines and anode connection lines) in the connection line region 10-2 may be substantially the same, and the arrangement may be any one or more of the following: positions of the lateral connection lines in the second direction Y, the width of the lateral connection lines, and the spacing between adjacent lateral connection lines. In an exemplary embodiment, the width and the spacing may be dimensions in the second direction Y.

In an exemplary embodiment, the trace density of the lateral connection lines in the normal region 10-1 and the trace density of the lateral connection lines in the connection line region 10-2 may be substantially the same, and the trace density may be any one or more of the following: an area of lateral connection lines per unit area, a sum of widths of a plurality of lateral connection lines per unit area, and a sum of lengths of a plurality of lateral connection lines per unit area, the length may be a dimension in the first direction X, and the width may be a dimension in the second direction Y.

In an exemplary embodiment, since the anode connection lines are not provided in the normal region and the anode connection lines are provided in the connection line region, there is a problem that the lateral connection lines below the anodes are uneven in the first region. In the present disclosure, dummy connection lines are provided in the first region, so that the number of lateral connection lines which overlap with anodes in the normal region and the connection line region are substantially the same, which not only effectively improves the uniformity of the lateral connection lines below the anodes, but also effectively improves the flatness of the anodes, and effectively improves color deviation and display quality. Further, by setting the arrangement of the lateral connection lines in the normal region and the connection line region to be substantially the same or similar, the trace density of lateral connection lines in the normal region and the connection line region to be substantially the same or similar, defects such as screen-off watermark (Mura) are less likely to occur, thereby improving the display quality.

In an exemplary embodiment, the dummy connection line 41 may be connected to the signal connection line 50 through a trace connection line 42. The signal connection line 50 may have a main body portion in a shape of a straight line or a bend line extending along the first direction X, and the trace connection line 42 may have a main body portion in a shape of a straight line or a bend line extending along the second direction Y. A first end of the trace connection line 42 is connected to the signal connection line 50, and a second end of the trace connection line 42 is connected to one or more dummy connection lines 41.

In an exemplary embodiment, in the first direction X, a trace connection line 42 may be disposed between adjacent anodes 40, and an orthographic projection of the trace connection line 42 on the base substrate is not overlapped with an orthographic projection of an anode 40 on the base substrate, thus not affecting the flatness of the anode.

In an exemplary embodiment, in the second direction Y, the signal connection lines 50 transmitting a same signal may be disposed one or more unit rows apart. For example, the signal connection lines 50 transmitting the same signal may be disposed in odd-numbered unit rows. As another example, the signal connection lines 50 transmitting the same signal may be disposed in even-numbered unit rows.

In an exemplary implementation, in a direction perpendicular to the display substrate, the display substrate may include a plurality of conductive layers arranged sequentially on the base substrate. In an embodiment, the dummy connection lines 41, the trace connection lines 42, and the signal connection lines 50 may be provided in the same conductive layer, and the dummy connection lines 41, the trace connection lines 42, and the signal connection lines 50 may be of an interconnected integral structure. In another embodiment, the dummy connection lines 41, the trace connection lines 42, and the signal connection lines 50 may be provided in different conductive layers, and the dummy connection lines 41, the trace connection lines 42, and the signal connection lines 50 may be connected to each other through vias. In still another embodiment, two of the dummy connection lines 41, the trace connection lines 42, and the signal connection lines 50 are provided in one conductive layer, and the other is provided in the another conductive layer, which is not limited here in the present disclosure.

In an exemplary embodiment, the plurality of conductive layers may at least include a first gate metal layer, a second gate metal layer, a first source-drain metal layer, a second source-drain metal layer, and a third source-drain metal layer, which are sequentially disposed in a direction away from the base substrate, and at least one of the dummy connection lines 41, the trace connection lines 42, and the signal connection lines 50 may be disposed in the third source-drain metal layer.

In an exemplary embodiment, the plurality of conductive layers may at least include a shielding layer, a first gate metal layer, a second gate metal layer, a first source-drain metal layer, and a second source-drain metal layer, which are sequentially disposed in a direction away from the base substrate, and at least one of the dummy connection lines 41, the trace connection lines 42, and the signal connection lines 50 may be disposed in the shielding layer.

In an exemplary embodiment, the signal connection line 50 with a main body portion extending along the first direction X may be connected to the first power supply line with a main body portion extending along the second direction Y, which not only forms a mesh communication structure for transmitting the first power supply signal, but also can effectively increase the trace density of the first power supply line, further reduce the resistance of the first power supply line, reduce the voltage drop of the first power supply signal, reduce power consumption, and improve display uniformity.

In another exemplary embodiment, the signal connection line 50 with a main body portion extending along the first direction X may be connected to the second power supply line with a main body portion extending along the second direction Y, which not only forms a mesh communication structure for transmitting the second power supply signal, but also can effectively increase the trace density of the second power supply line, further reduce the resistance of the second power supply line, reduce the voltage drop of the second power supply signal, and improve display uniformity.

In yet another exemplary embodiment, the signal connection line 50 with a main body portion extending along the first direction X may be connected with the initial signal line with a main body portion extending along the second direction Y, which not only forms a mesh communication structure for transmitting the initial signal, but also can effectively increase the trace density of the initial signal line, further reduce the resistance of the initial signal line, reduce the voltage drop of the initial signal, enhance the driving capability of the initial signal, and alleviate defects such as lateral stripes and watermarks caused by the insufficient driving capability of the initial signal.

In an exemplary embodiment, the light emitting structure layer may at least include an anode conductive layer provided on a side of the drive structure layer away from the base substrate, a pixel definition layer provided on a side of the anode conductive layer away from the base substrate, an organic light emitting layer provided on a side of the pixel definition layer away from the base substrate, and a cathode provided on a side of the organic light emitting layer away from the base substrate. The anode conductive layer may include a plurality of anodes, the pixel definition layer may include a plurality of pixel openings, the pixel openings expose the anodes, and the organic light emitting layer is connected to the anodes through the pixel openings.

In an exemplary embodiment, the light emitting structure layer may further include at least one auxiliary cathode, the auxiliary cathode and the anodes may be disposed in a same layer, an orthographic projection of the auxiliary cathode on the base substrate is at least partially overlapped with an orthographic projection of the second power supply line (a signal connection line connected to the second power supply line) on the base substrate, and the auxiliary cathode is connected to the second power supply line (the signal connection line connected to the second power supply line) through an auxiliary via, and the auxiliary cathode is configured to be connected to a subsequently formed cathode.

In an exemplary embodiment, after the organic light emitting layer is formed, a connection hole exposing the auxiliary cathode may be formed in a laser punching manner, so that the cathode is connected to the auxiliary cathode through the connection hole.

In an exemplary embodiment, a plurality of auxiliary cathodes may be periodically provided along the first direction X and the second direction Y to form the auxiliary cathodes of a mesh communication structure on the display substrate, which can further improve uniformity of the second power supply signal in the display substrate, enhance display uniformity, and improve display quality.

In some other embodiments, the auxiliary cathode may not be provided in the light emitting structure layer, and the cathode in the light emitting structure layer is directly connected to the second power supply line (the signal connection line 50 connected to the second power supply line) using a connection hole, which is not limited here in the present disclosure.

In an exemplary embodiment, the pixel definition layer may be made of a black organic material such as black polyimide or acrylic or black polyethylene terephthalate. Because the pixel definition layer can cover traces such as anode connection lines and dummy connection lines, the reflectivity of signal traces can be reduced, and the defect such as screen-off watermark can be effectively alleviated.

FIG. 14 is a schematic diagram of an arrangement of second regions according to an exemplary embodiment of the present disclosure. As illustrated in FIG. 14, the plurality of second regions 20 may include a first sub-region 20-1, a second sub-region 20-2, a third sub-region 20-3, a fourth sub-region 20-4, a fifth sub-region 20-5, a sixth sub-region 20-6, . . . an (n-5)-th sub-region 20-(n-5), an (n-4)-th sub-region 20-(n-4), an (n-3)-th sub-region 20-(n-3), an (n-2)-th sub-region 20-(n-2), an (n-1)-th sub-region 20-(n-1), and an n-th sub-region 20-n disposed sequentially along the first direction X.

In an exemplary embodiment, for the scan drive apparatus including 5 groups of gate drive apparatuses, the first sub-region 20-1 and the n-th sub-region 20-n may be provided with a first gate drive apparatus 121 that outputs a first scan signal line S1, the second sub-region 20-2 and the (n-1)-th sub-region 20-(n-1) may be provided with a second gate drive apparatus 122 that outputs a second scan signal line S2, the third sub-region 20-3 and the (n-2)-th sub-region 20-(n-2) may be provided with a third gate drive apparatus 123 that outputs a third scan signal line S3, the fourth sub region 20-4 and the (n-3)-th sub region 20-(n-3) can be provided with a fourth gate drive apparatus 124 that outputs a fourth scan signal line S4, and the fifth sub region 20-5 and the (n-4)-th sub region 20-(n-4) can be provided with a fifth gate drive apparatus 125 that outputs a light-emitting signal line EM, so that a bilateral drive structure of 5 groups of gate drive apparatuses is formed.

In an exemplary embodiment, each group of gate drive apparatuses may include a plurality of cascaded gate drive circuits, and the gate drive circuit in each stage is connected to a plurality of pixel drive circuits in one unit row through a scan signal line or a light emitting signal line to provide the plurality of pixel drive circuits in the unit row with a scan signal or a light emitting control signal.

In an exemplary embodiment, the plurality of pixel drive circuits in the first region and the plurality of gate drive circuits in the second region may be synchronously prepared using the same process, and no additional patterning process is required. In some possible embodiments, for some special display effects (such as light shielding, light transmission uniformity, etc.) or display optimization, one film layer or two film layers may be added to the second region, which is not limited here in the present disclosure.

In an exemplary embodiment, the scan drive apparatus may not be limited to including 5 groups of gate drive apparatuses, nor is it limited to using a bilateral drive structure, and the scan drive apparatus may include other number of groups of gate drive apparatuses and a single-sided drive structure, which is not limited here in the present disclosure.

In an exemplary embodiment, at least one sub-region of the sixth sub-region 20-6 to the (n-5)-th sub-region 20-(n-5) may be provided with at least one signal trace 60, and the signal trace 60 may include any one or more of the following: a first power supply line 61, a second power supply line 62, and an initial signal line 63.

In an exemplary embodiment, each sub-region of the sixth sub-region 20-6 to the (n-5)-th sub-region 20-(n-5) may be provided with a first power supply line 61 to reduce the resistance of the first power supply line 61, reduce the voltage drop of the first power supply signal, reduce power consumption, and improve display uniformity.

In another exemplary embodiment, each sub-region of the sixth sub-region 20-6 to the (n-5)-th sub-region 20-(n-5) may be provided with a second power supply line 62 to reduce the resistance of the second power supply line 62, reduce the voltage drop of the second power supply signal, and improve display uniformity.

In yet another exemplary embodiment, each sub-region of the sixth sub-region 20-6 to the (n-5)-th sub-region 20-(n-5) may be provided with an initial signal line 63 to reduce the resistance of the initial signal line 63, reduce the voltage drop of the initial signal, enhance the driving capability of the initial signal, and alleviate defects such as lateral stripes and watermarks caused by insufficient driving capability of the initial signal.

In yet another exemplary embodiment, each sub-region of the sixth sub-region 20-6 to the (n-5)-th sub-region 20-(n-5) may be provided with a first power supply line 61 and a second power supply line 62, respectively, or may be provided with a first power supply line 61 and an initial signal line 63, respectively, or may be provided with a second power supply line 62 and an initial signal line 63, respectively, or may be provided with a first power supply line 61, a second power supply line 62, and an initial signal line 63, respectively, which is not limited here in the present disclosure.

In an exemplary embodiment, since the drive structure layers in the sixth sub-region 20-6 to the (n-5)-th sub-region 20-(n-5) are not provided with gate drive apparatuses, the drive structure layers of these sub-regions may be provided with dummy drive circuits, and the structure, arrangement and dimension of the dummy drive circuits may be substantially the same as those of the pixel drive circuits in the first region, except that the dummy drive circuits are not connected to any light emitting device.

In an exemplary embodiment, at least one sub-region of the first sub-region 20-1 to the fifth sub-region 20-5 and the (n-4)-th sub-region 20-(n-4) to the nth sub-region 20-n may further be provided with at least one signal trace 60, and the signal trace 60 may include any one or more of the following: a first power supply line 61, a second power supply line 62, and an initial signal line 63.

In an exemplary embodiment, in at least one sub-region of the first sub-region 20-1 to the fifth sub-region 20-5, and the (n-4)-th sub-region 20-(n-4)-th to the n-th sub-region 20-n, the gate drive apparatus may be provided at a middle position of the sub-region in the first direction X, and the signal traces 60 may be provided at one side or two sides of the gate drive apparatus in the first direction X. For example, the at least one sub-region may be provided with at least one first power supply line 61 and at least one initial signal line 63, and the first power supply line 61 and the initial signal line 63 may be provided at two sides of the gate drive apparatus. As another example, the at least one sub-region may be provided with at least one second power supply line 62 and at least one initial signal line 63, and the second power supply line 62 and the initial signal line 63 may be provided at two sides of the gate drive apparatus. For another example, the at least one sub-region may be provided with at least one first power supply line 61, at least one second power supply line 62, and at least one initial signal line 63; and the first power supply line 61, the second power supply line 62, and the initial signal line 63 may be provided at two sides of the gate drive apparatus.

In an exemplary embodiment, in a direction perpendicular to the display substrate, the signal trace 60 may be disposed at a side of the clock signal line away from the base substrate, and the signal trace 60 transmitting a DC signal may shield the clock signal line, avoid coupling between the anode connection line connecting the light emitting device and the clock signal line, and avoid affecting the stability of the anode voltages in the gate drive apparatus and the light emitting device, and improve the driving performance of the gate drive apparatus.

In an embodiment, each sub-region of the first sub-region 20-1 to the fifth sub-region 20-5 and the (n-4)-th sub-region 20-(n-4) to the n-th sub-region 20-n may be provided with a first power supply line 61, and an orthographic projection of the first power supply line 61 on the base substrate is at least partially overlapped with an orthographic projection of the clock signal line in the gate drive apparatus on the base substrate, which can not only shield the clock signal, but also further reduce the resistance of the first power supply line 61, reduce the voltage drop of the first power supply signal, reduce the power consumption, and improve the display uniformity.

In another embodiment, each sub-region of the first sub-region 20-1 to the fifth sub-region 20-5 and the (n-4)-th sub-region 20-(n-4) to the n-th sub-region 20-n may be provided with a second power supply line 62, and an orthographic projection of the second power supply line 62 on the base substrate is at least partially overlapped with an orthographic projection of the clock signal line in the gate drive apparatus on the base substrate, which not only shields the clock signal, but also further reduces the resistance of the second power supply line 62, reduces the voltage drop of the second power supply signal, and improves the display uniformity.

In another embodiment, each sub-region of the first sub-region 20-1 to the fifth sub-region 20-5 and the (n-4)-th sub-region 20-(n-4) to the n-th sub-region 20-n may be provided with an initial signal line 63, and an orthographic projection of the initial signal line 63 on the base substrate is at least partially overlapped with an orthographic projection of the clock signal line in the gate drive apparatus on the base substrate, which can not only shield the clock signal, but also further reduce the resistance of the initial signal line 63, reduce the voltage drop of the initial signal, enhance the driving capability of the initial signal, and alleviate the defects such as lateral stripes and watermarks caused by insufficient driving capability of the initial signal.

In yet another exemplary embodiment, each sub-region of the first sub-region 20-1 to the fifth sub-region 20-5 and the (n-4)-th sub-region 20-(n-4) to the n-th sub-region 20-n may be provided with a first power supply line 61 and a second power supply line 62, respectively, or may be provided with a first power supply line 61 and an initial signal line 63, respectively, or may be provided with a second power supply line 62 and an initial signal line 63, respectively, or may be provided with a first power supply line 61, a second power supply line 62, and an initial signal line 63, respectively, which is not limited here in the present disclosure.

In an exemplary embodiment, the display region may be further provided with a signal connection line extending along the first direction X, and signal connection lines extending horizontally and signal traces extending vertically may be connected to each other to form a mesh communication structure on the entire surface of the display region.

FIG. 15 is an enlarged view of region D in FIG. 14, and schematically illustrates structures of the gate drive circuits and the signal traces in the second region. As illustrated in FIG. 15, a plurality of cascaded gate drive circuits GOA may be sequentially provided along the second direction Y, and at least one gate drive circuit GOA may be connected to a scan start signal line STV, a first clock signal line CLK, a second clock signal line CLKB, a high-level signal line VGH, and a low-level signal line VGL, respectively.

In an exemplary embodiment, the scan start signal line STV, the first clock signal line CLK, the second clock signal line CLKB, the high-level signal line VGH, and the low-level signal line VGL may be in a shape of a straight line or a bend line extending along the second direction Y, the high-level signal line VGH may be provided at a side of the gate drive circuit GOA in the first direction X, and other gate signal lines may be provided at a side of the gate drive circuit GOA in an opposite direction of the first direction X.

In an exemplary embodiment, at least one or more of the first power supply line 61 and the initial signal line 63 may be provided at a side of the high-level signal line VGH in the first direction X, at least one or more of the first power supply line 61 and the initial signal line 63 may be provided at a side of the scan start signal line STV in an opposite direction of the first direction X, and the first power supply line 61 and the initial signal line 63 may be in a shape of a straight line or a bend line extending along the second direction Y.

In an exemplary embodiment, at least one second power supply line 62 may be provided in a region where the gate drive circuit GOA and the gate signal line are located, and the second power supply line 62 may be in a shape of a straight line or a bend line extending along the second direction Y. The second power supply lines 62 may be plural, and the plurality of second power supply lines 62 may have widths that are the same or different, or may be merged into a wider one. An orthographic projection of the second power supply line 62 on the base substrate is at least partially overlapped with orthographic projections of the first clock signal line CLK and the second clock signal line CLKB on the base substrate, so that the second power supply line 62 can shield the clock signal, avoid coupling between the connection line connecting the light emitting device and the clock signal line, and improve the driving performance of the gate drive apparatus.

In an exemplary embodiment, the signal connection line 50 may be in a shape of a straight line shape or a bend line shape extending along the first direction X, and in the second direction Y, the signal connection line 50 may be provided between two cascaded gate drive circuits GOA to complete lateral bridging.

In an exemplary embodiment, at least one laterally extending signal connection line 50 may be connected to a vertically extending first power supply line 61 to form a mesh communication structure for transmitting the first power supply signal on the entire surface of the display region, and/or at least one laterally extending signal connection line 50 may be connected to a vertically extending second power supply line 62 to form a mesh communication structure for transmitting the second power supply signal on entire surface of in the display region, and/or at least one laterally extending signal connection line 50 may be connected to a vertically extending initial signal line 63 to form a mesh communication structure for transmitting the initial signal on the entire surface of the display region, which is not limited here in the present disclosure.

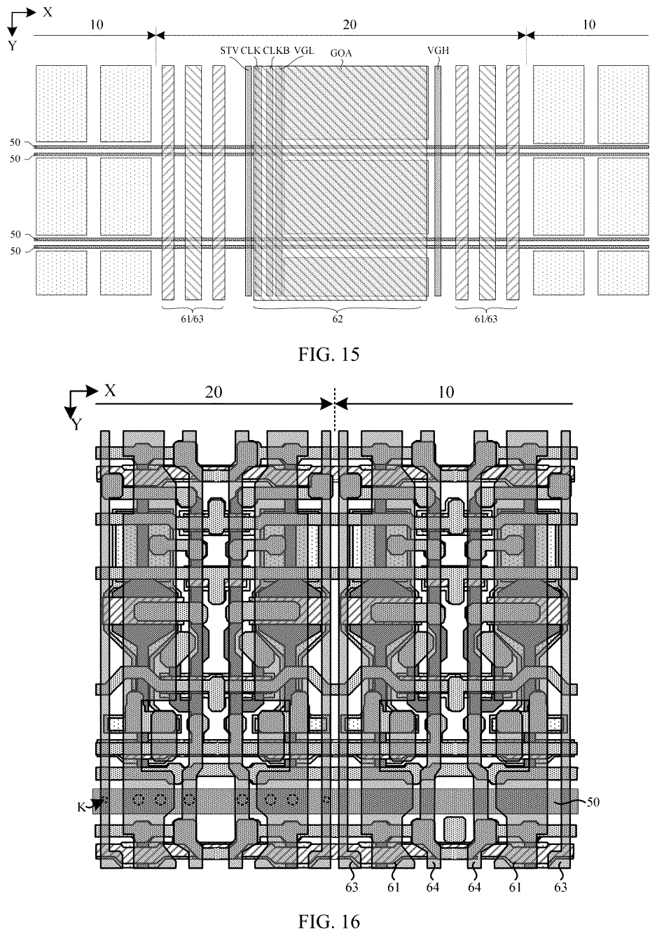

FIG. 16 is an enlarged view of region E in FIG. 14, and schematically illustrates a connection structure of signal lines in the dummy drive circuit. As shown in FIG. 16, the pixel drive circuit (the first pixel drive circuit and the second pixel drive circuit) in the first region 10 may include a storage capacitor and a plurality of transistors, and is connected to the data signal line 64, the first power supply line 61, and the initial signal line 63, respectively. The structure of some of dummy drive circuits in the second region 20 may be substantially the same as that of the pixel drive circuit in the first region, but the data signal line 64, the first power supply line 61, and/or the initial signal line 63 connected to the dummy drive circuit may be connected to the signal connection line 50 through vias K, respectively. When the signal connection line 50 is configured to be connected to the second power supply line 62, vertical signal lines originally used for transmitting the data signal, the first power supply signal, and/or the initial signal are shorted with the second power supply line 62 through the signal connection line 50, which can maximize the trace density of the second power supply line 62.

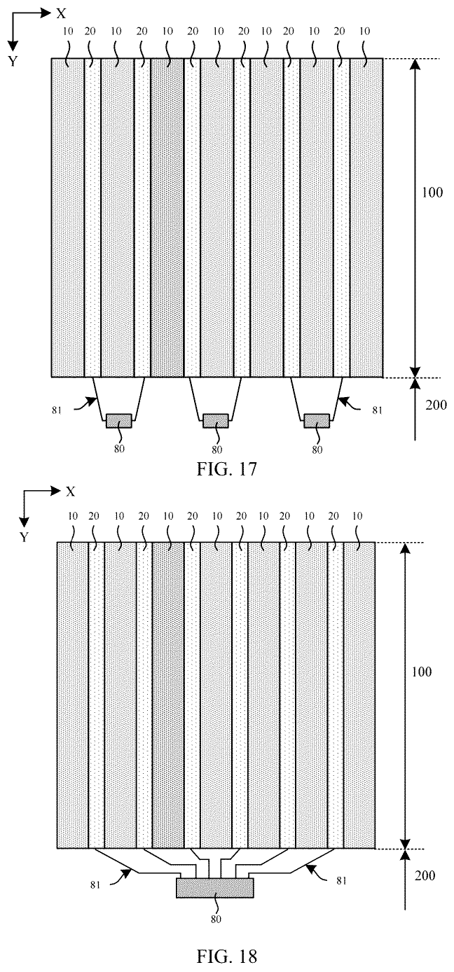

FIGS. 17 and 18 are schematic diagrams of gate lead-out lines according to exemplary embodiments of the present disclosure. In an exemplary embodiment, the display substrate may at least include a display region 100 and a bonding region 200 located on a side of the display region 100 in the second direction Y. The display region 100 may include first regions 10 and second regions 20 alternately disposed along the first direction X, the first region 10 may include a plurality of pixel drive circuits, and the second region 20 may include a plurality of gate drive circuits. The bonding region 200 may at least include a drive chip region, and the drive chip region may at least include an Integrated Circuit (IC) 80, the integrated circuit 80 is configured to be connected to a plurality of data lead-out lines (not shown) and a plurality of gate lead-out lines 81, the plurality of data lead-out lines are configured to be connected to a plurality of data signal lines in the plurality of first regions 10, and the plurality of gate lead-out lines 81 are configured to be connected to scan start signal lines STV, first clock signal lines CLK, second clock signal lines CLKB, high-level signal lines VGH, and low-level signal lines VGL in the plurality of second regions 20.

In an exemplary embodiment, for a bonding structure in which the chip is bonded to a flexible base substrate (Chip On Pi, COP for short), the gate lead-out lines 81 may be connected to pins on two sides of the integrated circuit 80, so that the integrated circuit 80 provides gate signals to the gate drive circuits in the plurality of second regions 20, as shown in FIG. 17. Alternatively, wiring may be arranged in a region between an output pin (a pin on a side of the integrated circuit 80 close to the display region) and an input pin (a pin on a side of the integrated circuit 80 away from the display region), so that the gate lead-out lines 81 and the output pins are connected, and the spacings of the plurality of gate lead-out lines 81 are substantially the same, so that the integrated circuit 80 provides gate signals to the gate drive circuits in the plurality of second regions 20 as shown in FIG. 18. Alternatively, by interleaving the gate signals and data signals the integrated circuit 80 provides gate signals to gate drive circuits in the plurality of second regions 20. Thereby, the present disclosure is not limited thereto.

In an exemplary embodiment, for a bonding structure in which a chip is bonded to a Chip On Film (COF for short), gate lead-out lines may be arranged on a flexible circuit board FPC, so that the integrated circuit provides gate signals to gate drive circuits in the plurality of second regions, which is not limited here in the present disclosure.

An exemplary embodiment of the present disclosure provides a display substrate, in which first regions and second regions are alternately arranged in a display region, the first region is provided with pixel drive circuits, and the second region is provided with gate drive circuits and signal traces, both the gate drive circuits and the signal traces are provided in the display region, without occupying a space of a bezel region, thus effectively reducing the bezel width of a display apparatus, and the bezel width can be reduced to a width less than 0.5 mm, a screen-to-body ratio is increased, and implementation of a full-screen display is facilitated.

In the embodiment of the present disclosure, the pixel drive circuits are provided in the first region in a compression mode, sot that the pixel drive circuits in the first region are connected to the light emitting devices in the second region, and both the first region and the second region can achieve normal display, which not only does not affect the display resolution, but also is beneficial to realizing high display resolution.

By providing the dummy connection lines, the embodiment of the present disclosure can not only effectively improve the uniformity of lateral connection lines below the anode, but also effectively improve the flatness of the anode, and effectively improve the color deviation and the display quality. In the embodiment of the present disclosure, the arrangements of the lateral connection lines in the normal region and the connection line region are substantially the same or similar, the trace densities of the lateral connection lines in the normal region and the connection line region are substantially the same or similar, so that the defects such as screen-off watermark (Mura) are less likely to occur, thereby improving the display quality.

In the embodiment of the present disclosure, the dummy connection lines are connected to the signal lead lines, which effectively increases the trace density of the signal lead lines, can further reduce the resistance of the signal lead lines, reduce the voltage drop of the signal and the power consumption, and improve the display uniformity.

In the embodiment of the present disclosure, the signal connection line with a main body portion extending in the first direction is connected to the signal lead with a main body portion extending in the second direction, to form a mesh communication structure on the entire surface of the display region, which not only can effectively reduce the resistance of the signal lead and the voltage drop of the signal, but also can effectively improve the uniformity of the signal in the display substrate, the display uniformity, and the display quality.

In the embodiment of the present disclosure, the signal lead line overlaps with the clock signal line, so that the signal trace for transmitting the DC signal can shield the clock signal line, which effectively improves the driving performance of the gate drive apparatus.

In the embodiment of the present disclosure, auxiliary cathodes are provided, and the auxiliary cathodes form a mesh communication structure on the display substrate, which can further improve uniformity of the second power supply signal in the display substrate, enhance display uniformity, and improve display quality.

In the embodiment of the present disclosure, a black pixel definition layer is provided, which can reduce the reflectivity of signal traces, and effectively alleviate the defects such as screen-off watermark.

The manufacturing process in an embodiment of the present disclosure may be compatible well with an existing manufacturing process, is simple in process implementation, is easy to implement, and has a high production efficiency, a low production cost, and a high yield.

The foregoing structure in the present disclosure is only exemplary description. In an exemplary embodiment, the corresponding structure may be changed according to actual needs, which is not limited in the present disclosure.

In an exemplary embodiment, the display substrate according to the present disclosure may be applied to a display apparatus with a pixel drive circuit, such as an OLED, quantum dot display (QLED), light emitting diode display (Micro LED or Mini LED), or Quantum Dot Light Emitting Diode display (QDLED), which is not limited here in the present disclosure.

The present disclosure further provides a manufacturing method for a display substrate, to manufacture the display substrate according to the foregoing embodiments. In an exemplary embodiment, the display substrate includes a plurality of first regions and a plurality of second regions, a first region of the plurality of first regions and a second region of the plurality of second regions each are in a shape of a strip extending along a second direction, the plurality of first regions and the plurality of second regions are alternately disposed along a first direction, the first direction and the second direction intersect. The manufacturing method may include: forming a drive structure layer on a base substrate; wherein the drive structure layer of the first region includes a plurality of pixel drive circuits, and the drive structure layer of the second region includes at least one gate drive apparatus and/or at least one signal trace; and forming a light emitting structure layer on a side of the drive structure layer away from the base substrate; wherein the light emitting structure layer of the first region includes a plurality of first light emitting devices, the light emitting structure layer of the second region includes a plurality of second light emitting devices, at least one first light emitting device in the first region is connected to at least one pixel drive circuit in the first region, and at least one second light emitting device in the second region is connected to at least one pixel drive circuit in the first region.

A display apparatus which includes the aforementioned display substrate is also provided in the present disclosure. The display apparatus may be any product or component with a display function, such as a mobile phone, a tablet computer, a television, a display, a laptop computer, a digital photo frame, and a navigator, and the screen shape may be spliced into a borderless display such as a cylindrical, surrounding screen, or a spherical. The embodiments of the present invention are not limited thereto.

Although embodiments disclosed in the present disclosure are as above, it should be noted that the above embodiments are exemplary only rather than restrictive. Therefore, the present disclosure is not limited to what is specifically shown and described here. Various modifications, substitutions, or omissions may be made in forms and details of implementations without departing from the scope of the present disclosure.

1. A display substrate, comprising a plurality of first regions and a plurality of second regions, wherein a first region of the plurality of first regions and a second region of the plurality of second regions are in a shape of a strip extending along a second direction, the plurality of first regions and the plurality of second regions are alternately disposed along a first direction, the first direction and the second direction intersects; in a direction perpendicular to the display substrate, a display region comprises a drive structure layer disposed on a base substrate, and a light emitting structure layer disposed on a side of the drive structure layer away from the base substrate; a drive structure layer of the first region comprises a plurality of pixel drive circuits, a drive structure layer of the second region comprises at least one gate drive apparatus and/or at least one signal trace, a light emitting structure layer of the first region comprises a plurality of first light emitting devices, and a light emitting structure layer of the second region comprises a plurality of second light emitting devices; at least one first light emitting device in the first region is connected to at least one pixel drive circuit in the first region, and at least one second light emitting device in the second region is connected to at least one pixel drive circuit in the first region.

2. The display substrate according to claim 1, wherein the drive structure layer of the first region comprises a plurality of circuit repeating units, an orthographic projection of at least one circuit repeating unit on the base substrate has a first area, the light emitting structure layer of the first region comprises a plurality of light emitting repeating units, an orthographic projection of at least one light emitting repeating unit on the base substrate has a second area, and a ratio of the first area to the second area is 0.95 to 1.05; the at least one circuit repeating unit comprises M+m pixel drive circuits, and the at least one light emitting repeating unit comprises M first light emitting devices; wherein M is an integer multiple of 2 or an integer multiple of 3, and m is a positive integer greater than or equal to 1.

3. The display substrate according to claim 2, wherein a pixel drive circuit in the at least one circuit repeating unit at least comprises a first pixel drive circuit and a second pixel drive circuit, at least one first pixel drive circuit is connected to the at least one first light emitting device, and an orthographic projection of the at least one first pixel drive circuit on the base substrate is at least partially overlapped with an orthographic projection of the at least one first light emitting device on the base substrate; at least one second pixel drive circuit is connected to the at least one second light emitting device through an anode connection line, and an orthographic projection of the at least one second pixel drive circuit on the base substrate is not overlapped with an orthographic projection of the at least one second light emitting device on the base substrate.

4. The display substrate according to claim 3, wherein the second region has a first center line that is a straight line bisecting the second region in the first direction and extending along the second direction; the second region at least comprises a first side repeating unit located at a side of the first center line in an opposite direction of the first direction, and a second side repeating unit located at a side of the first center line in the first direction, and the first side repeating unit and the second side repeating unit each comprises N second light emitting devices, and Nis an integer multiple of 3 or an integer multiple of 4.

5. The display substrate according to claim 4, wherein the first region at least comprises a first side region located at a side of the second region in an opposite direction of the first direction, and a second side region located at a side of the second region in the first direction; at least one second light emitting device in the first side repeating unit is connected to at least one second pixel drive circuit in the first side region through an anode connection line, and at least one second light emitting device in the second side repeating unit is connected to at least one second pixel drive circuit in the second side region through an anode connection line.

6. The display substrate according to claim 5, wherein the first side region at least comprises a first circuit repeating unit and a second circuit repeating unit, the first circuit repeating unit is located at a side of the second region in an opposite direction of the first direction, the second circuit repeating unit is located at a side of the first circuit repeating unit away from the second region; the second side region at least comprises an eleventh circuit repeating unit and a twelfth circuit repeating unit, the eleventh circuit repeating unit is located at a side of the second region in the first direction, and the twelfth circuit repeating unit is located at a side of the eleventh circuit repeating unit away from the second region; the first side repeating unit comprises a first light emitting device group and a second light emitting device group sequentially disposed along the first direction, and the second side repeating unit comprises a third light emitting device group and a fourth light emitting device group sequentially disposed along the first direction; at least one second light emitting device in the first light emitting device group is connected to at least one second pixel drive circuit in the first circuit repeating unit through a first anode connection line, at least one second light emitting device in the second light emitting device group is connected to at least one second pixel drive circuit in the second circuit repeating unit through a second anode connection line, at least one second light emitting device in the third light emitting device group is connected to at least one second pixel drive circuit in the eleventh circuit repeating unit through an eleventh anode connection line, and at least one second light emitting device in the fourth light emitting device group is connected to at least one second pixel drive circuit in the twelfth circuit repeating unit through a twelfth anode connection line.

7. The display substrate according to claim 6, wherein a second length of at least one second anode connection line is greater than a first length of at least one first anode connection line, a fourth length of at least one twelfth anode connection line is greater than a third length of at least one eleventh anode connection line, and the first length, the second length, the third length, and the fourth length are dimensions in the first direction.

8. The display substrate according to claim 7, wherein the third length of the at least one eleventh anode connection line is greater than the first length of the at least one first anode connection line, and the fourth length of the at least one twelfth anode connection line is greater than the second length of the at least one second anode connection line.

9. The display substrate according to claim 3, wherein a material of the anode connection line is a metal material, or the material of the anode connection line is a transparent conductive material.

10. The display substrate according to claim 3, wherein a first light emitting device of the plurality of first light emitting devices and a second light emitting device of the plurality of second light emitting devices each comprise an anode, an anode of at least one second light emitting device is connected to at least one second pixel drive circuit through the anode connection line, at least one anode connection line is in a shape of a straight line or bend line extending along the first direction, and an orthographic projection of the at least one anode connection line on the base substrate is at least partially overlapped with an orthographic projection of the anode of at least one first light emitting device on the base substrate.

11. The display substrate according to claim 10, wherein the first region further comprises at least one dummy connection line, the at least one dummy connection line is in a shape of a straight line or a bend line extending along the first direction, and an orthographic projection of the at least one dummy connection line on the base substrate is at least partially overlapped with an orthographic projection of an anode of at least one first light emitting device on the base substrate.

12. The display substrate according to claim 11, wherein the first region at least comprises a normal region and a connection line region, the normal region is a region where the anode connection line is not provided, and the connection line region is a region where the anode connection line is provided; an orthographic projection of at least one anode in the normal region on the base substrate is at least partially overlapped with orthographic projections of K1 dummy connection lines on the base substrate, an orthographic projection of at least one anode in the connection line region on the base substrate is at least partially overlapped with orthographic projections of K2 dummy connection lines and K3 anode connection lines on the base substrate, wherein K1=K2+K3, K1, K2, and K3 are all positive integers greater than or equal to 1.

13. The display substrate according to claim 12, wherein an arrangement of dummy connection lines in the normal region is the same as an arrangement of dummy connection lines and anode connection lines in the connection line region, and the arrangement is any one or more of: a position of a connection line in the second direction, a width of a connection line, and a spacing between adjacent connection lines, wherein the width and the spacing are dimensions in the second direction.

14. The display substrate according to claim 12, wherein a trace density of dummy connection lines in the normal region is the same as a trace density of dummy connection lines and anode connection lines in the connection line region, and the trace density is an area of connection lines per unit area.

15. The display substrate according to claim 11, wherein at least one dummy connection line is connected to at least one signal connection line through at least one trace connection line, the trace connection line is in a shape of a straight line or a bend line extending along the second direction, the trace connection line is disposed between two anodes adjacent in the first direction, and an orthographic projection of the trace connection line on the base substrate is not overlapped with orthographic projections of the anodes on the base substrate.

16. The display substrate according to claim 15, wherein the signal connection line is in a shape of a straight line or a bend line extending along the first direction; at least one signal connection line is connected to a first power supply line which serves as the signal trace and a main body portion of which extends along the second direction to form a mesh communication structure for transmitting a first power supply signal, and/or at least one signal connection line is connected to a second power supply line which serves as the signal trace and a main body portion of which extends along the second direction to form a mesh communication structure for transmitting a second power supply signal, and/or at least one signal connection line is connected to an initial signal line which serves as the signal trace and a main body portion of which extends along the second direction to form a mesh communication structure for transmitting an initial signal.

17. The display substrate according to claim 16, wherein the at least one gate drive apparatus comprises a plurality of gate drive circuits sequentially disposed and cascaded along the second direction, at least one gate drive circuit is connected to a first clock signal line and a second clock signal line, the first clock signal line and the second clock signal line are in a shape of a straight line or a bend line extending along the second direction; in at least one second region, an orthographic projection of the first power supply line on the base substrate is at least partially overlapped with orthographic projections of the first clock signal line and the second clock signal line on the base substrate, and/or an orthographic projection of the second power supply line on the base substrate is at least partially overlapped with orthographic projections of the first clock signal line and the second clock signal line on the base substrate, and/or an orthographic projection of the initial signal line on the base substrate is at least partially overlapped with orthographic projections of the first clock signal line and the second clock signal line on the base substrate.

18. The display substrate according to claim 17, wherein at least one signal connection line is disposed between two cascaded gate drive circuits in the second direction.

19. A display apparatus, comprising the display substrate according to claim 1.

20. A manufacturing method for a display substrate, wherein the display substrate comprises a plurality of first regions and a plurality of second regions, a first region of the plurality of first regions and a second region of the plurality of second regions are in a shape of a strip extending along a second direction, the plurality of first regions and the plurality of second regions are alternately disposed along a first direction, the first direction and the second direction intersect; the manufacturing method comprises:
forming a drive structure layer on a base substrate; wherein the drive structure layer of the first region comprises a plurality of pixel drive circuits, and the drive structure layer of the second region comprises at least one gate drive apparatus and/or at least one signal trace; and
forming a light emitting structure layer on a side of the drive structure layer away from the base substrate; wherein the light emitting structure layer of the first region comprises a plurality of first light emitting devices, the light emitting structure layer of the second region comprises a plurality of second light emitting devices, at least one first light emitting device in the first region is connected to at least one pixel drive circuit in the first region, and at least one second light emitting device in the second region is connected to at least one pixel drive circuit in the first region.
